(19) United States
(12) Patent Application Publication
(10) Pub. No.: US 2026/0372210 A1
(43) Pub. Date: Nov. 19, 2026

(54) NON-VOLATILE MEMORY DEVICE INCLUDING VERTICALLY STACKED MEMORY CHIPS

(71) Applicant: SAMSUNG ELECTRONICS CO., LTD., Suwon-si (KR)

(72) Inventors: Suhyun KIM, Suwon-si (KR); Youngseok JEONG, Suwon-si (KR); Seunghwan SONG, Suwon-si (KR); Kiwhan SONG, Suwon-si (KR); Yoonjung KIM, Suwon-si (KR); Wandong KIM, Suwon-si (KR)

(73) Assignee: SAMSUNG ELECTRONICS CO., LTD., Suwon-si (KR)

(21) Appl. No.: 19/665,472

(22) Filed: May 1, 2026

(30) Foreign Application Priority Data
May 14, 2025 (KR) 10-2025-0062847
Nov. 25, 2025 (KR) 10-2025-0181033

(51) Int. Cl. H10W 90/20; G11C 16/10; G11C 16/26; H10B 80/00; H10W 90/00

(52) U.S. Cl. CPC H10W 90/297; G11C 16/10; G11C 16/26; H10B 80/00; H10W 90/401; H10W 90/722

(57) ABSTRACT

A non-volatile memory device includes a plurality of memory chips configured to communicate with a controller through a plurality of channels. The memory chips are connected to each other through a spiral routing structure and stacked in a vertical direction. The memory chips include a first memory chip including a first input/output circuit and a first pin in a first region, the first input/output circuit and the first pin being connected to a first channel, and a second memory chip including a second input/output circuit and a second pin in a second region, the second input/output circuit and the second pin being connected to the first channel. The second memory chip is stacked on the first memory chip with a first angle rotation in a horizontal direction, relative to the first memory chip. The second region has the first angle rotation in the horizontal direction, relative to the first region.

### CROSS-REFERENCE TO RELATED APPLICATIONS

This application is based on and claims priority under 35 U.S.C. § 119 to Korean Patent Application Nos. 10-2025-0062847, filed on May 14, 2025 and 10-2025-0181033, filed on Nov. 25, 2025, in the Ministry of Intellectual Property, Republic of Korea, the disclosures of which are incorporated by reference herein in their entirety.

### BACKGROUND

The disclosure relates to a memory device, and more particularly, to a nonvolatile memory device including vertically stacked memory chips.

Recently, with increases in data throughput and demand for high-performance computing, there is increasing demand for storage devices that simultaneously provide high read/write speed and bandwidth. In particular, in the fields of artificial intelligence processing, big data analysis, and real-time streaming, bandwidth of existing NAND flash-based storage devices may limit system performance. In this context, new flash memory structures capable of providing higher data transmission performance are required, but NAND flash memory devices according to the related art struggle to provide sufficient bandwidth due to an interface limitation and an internal bottleneck.

### SUMMARY

The disclosure provides a nonvolatile memory device capable of providing increased data transmission bandwidth.

According to an aspect of the disclosure, there is provided a nonvolatile memory device including a plurality of memory chips configured to communicate with a controller through a plurality of channels including a first channel, the plurality of memory chips being connected to each other through a spiral routing structure and stacked in a vertical direction, wherein the plurality of memory chips include a first memory chip including a first input/output circuit and a first pin in a first region, the first input/output circuit and the first pin being connected to the first channel, and a second memory chip including a second input/output circuit and a second pin in a second region, the second input/output circuit and the second pin being connected to the first channel, the second memory chip being stacked on the first memory chip with a first angle rotation in a horizontal direction relative to the first memory chip, and the second region has the first angle rotation in the horizontal direction relative to the first region.

According to another aspect of the disclosure, there is provided a nonvolatile memory device including a plurality of memory chips configured to communicate with a controller through a plurality of channels including a first channel and a second channel, the plurality of memory chips being connected to each other through a spiral routing structure and stacked in a vertical direction, wherein the plurality of memory chips include a first memory chip including a first input/output circuit and a first pin in a first region, the first input/output circuit and the first pin being connected to the first channel, a second memory chip including a second input/output circuit and a second pin in a second region, the second input/output circuit and the second pin being connected to the second channel, the second memory chip being stacked on the first memory chip, and a third memory chip including a third input/output circuit and a third pin in a third region, the third input/output circuit and the third pin being connected to the first channel, the third memory chip being stacked on the second memory chip with a first angle rotation in a horizontal direction relative to the second memory chip, the first region and the second region overlap each other in the vertical direction, and the third region has the first angle rotation in the horizontal direction relative to the second region.

According to another aspect of the disclosure, there is provided a nonvolatile memory device including a plurality of memory chips configured to communicate with a controller through a plurality of channels, the plurality of memory chips being connected to each other through a spiral routing structure and stacked in a vertical direction, wherein each of the plurality of memory chips includes at least one first input/output group in a first through silicon via (TSV) zone, at least one second input/output group in a second TSV zone spaced apart from the first TSV zone, first devices connected to the at least one first input/output group through a first redistribution pattern, and second devices connected to the at least one second input/output group through a second redistribution pattern, and at least one of the plurality of memory chips is stacked with a first angle rotation.

### BRIEF DESCRIPTION OF THE DRAWINGS

Embodiments will be more clearly understood from the following detailed description taken in conjunction with the accompanying drawings.

FIG. 1 is a block diagram of a storage device according to an embodiment.

FIG. 2 schematically illustrates the structure of a memory device, according to an embodiment.

FIG. 3 is a perspective view of a memory device according to an embodiment.

FIG. 4 is a block diagram of a storage device according to an embodiment.

FIG. 5 is a perspective view of a memory device in FIG. 4, according to an embodiment.

FIGS. 6A and 6B respectively illustrate input/output (I/O) arrays according to embodiments.

FIG. 7 illustrates I/O units according to an embodiment.

FIG. 8 illustrates I/O units according to an embodiment.

FIG. 9 is a block diagram of a storage device according to an embodiment.

FIG. 10 is a perspective view of a memory device in FIG. 9, according to an embodiment.

FIG. 11 illustrates an I/O array according to an embodiment.

FIG. 12 illustrates I/O units according to an embodiment.

FIG. 13 illustrates I/O units according to an embodiment.

FIG. 14 illustrates an I/O group according to an embodiment.

FIG. 15 illustrates a memory chip according to an embodiment.

FIG. 16 illustrates an example of a vertical arrangement of I/O groups, according to an embodiment.

FIG. 17 illustrates an example of an arrangement of first to fourth memory chips, according to an embodiment.

FIG. 18 illustrates an example of an arrangement of first to fourth memory chips, according to an embodiment.

FIGS. 19A and 19B respectively illustrate examples of arrangements of first to fourth memory chips, according to embodiments.

FIGS. 20A and 20B respectively illustrate examples of arrangements of first to fourth memory chips, according to embodiments.

FIG. 21A illustrates a memory chip according to an embodiment, and FIG. 21B illustrates an example of an arrangement of first to fourth memory chips, according to an embodiment.

FIG. 22 is a block diagram of a system according to an embodiment.

### DETAILED DESCRIPTION OF THE EMBODIMENTS

Hereinafter, various embodiments will be described in detail with reference to the accompanying drawings. In the drawings, like reference characters denote like elements, and redundant descriptions thereof will be omitted.

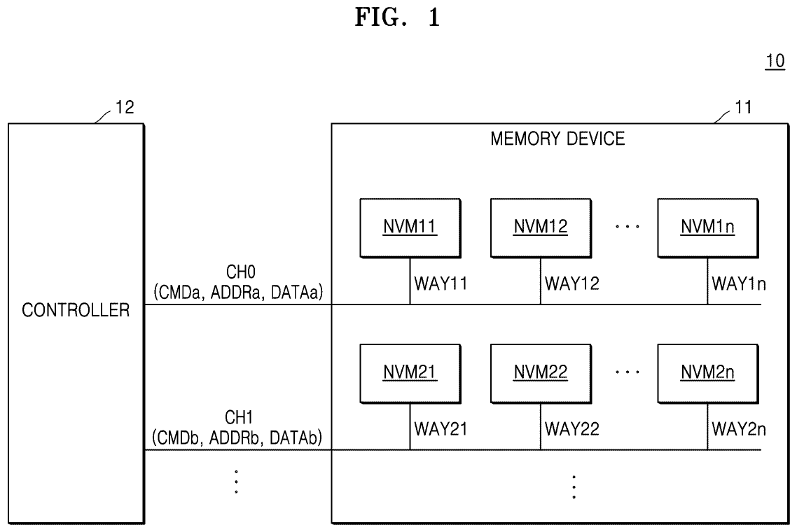

FIG. 1 is a block diagram of a storage device 10 according to an embodiment.

Referring to FIG. 1, the storage device 10 may include a memory device 11 and a controller 12. The storage device 10 may support a plurality of channels including a first channel CH0 and a second channel CH1. The memory device 11 may include a plurality of nonvolatile memories NVM11 to NVM2n, where “n” is a positive integer, and may thus be referred to as a “nonvolatile memory device.” The nonvolatile memories NVM11, NVM12 to NVM1n of the memory device 11 may be connected to the first channel CH0 through ways WAY11, WAY12 to WAY1n, respectively, and the nonvolatile memories NVM21, NVM22 to NVM2n of the memory device 11 may be connected to the second channel CH1 through ways WAY21, WAY22 to WAY2n, respectively. For example, each of the nonvolatile memories NVM11 to NVM2n may include, but is not limited to, a chip or a die.

In an embodiment, the nonvolatile memories NVM11 to NVM1n may be vertically stacked, thereby forming a first stack, and the nonvolatile memories NVM21 to NVM2n may be vertically stacked, thereby forming a second stack. In an embodiment, the first stack and the second stack may be vertically stacked. For example, the second stack may be above the first stack, and the first and second stacks may be electrically connected to each other via a through silicon via (TSV) structure. However, the disclosure is not limited thereto. In some embodiments, the first stack and the second stack may be horizontally arranged.

Each of the nonvolatile memories NVM11 to NVM2n may include a spiral routing stack. Specifically, each of the nonvolatile memories NVM11 to NVM2n may include a plurality of pins (e.g., TSVs), which respectively correspond to a plurality of channels, and a plurality of redistribution layers, which are respectively connected to the pins and arranged in a spiral shape so as to be connected to each other, thereby implementing a spiral routing stack. Accordingly, a spiral routing stack may be referred to as a spiral input/output (I/O) stack.

For example, when the nonvolatile memories NVM11 to NVM1n are vertically stacked so as to form the first stack, the nonvolatile memories NVM11 to NVM1n may be connected to each other through a first spiral routing structure. When the nonvolatile memories NVM21 to NVM2n are vertically stacked so as to form the second stack, the nonvolatile memories NVM21 to NVM2n may be connected to each other through a second spiral routing structure. In the disclosure, a spiral routing structure refers to a structure that includes a plurality of spiral routing stacks.

In an embodiment, at least one of the nonvolatile memories NVM11 to NVM1n in the first stack may be stacked with a first angle rotation. For example, the first angle rotation may be by 90 degrees, 180 degrees, or 270 degrees. In an embodiment, at least one of the nonvolatile memories NVM21 to NVM2n in the second stack may be stacked with a second angle rotation. For example, the second angle rotation may be by 90 degrees, 180 degrees, or 270 degrees. In an embodiment, the first angle rotation may be the same as the second angle rotation. In an embodiment, the first angle rotation may be different from the second angle rotation.

The controller 12 may select one of nonvolatile memories, which are connected to each channel, through the channel and exchange signals with the selected nonvolatile memory. For example, the controller 12 may select the nonvolatile memory NVM11 among the nonvolatile memories NVM11 to NVM1n connected to the first channel CH0. The controller 12 may transmit a command CMDa, an address ADDRa, and data DATAa to the selected nonvolatile memory NVM11 through the first channel CH0 or may receive the data DATAa from the selected nonvolatile memory NVM11 .

The controller 12 may also exchange signals with the memory device 11 in parallel through different channels. For example, the controller 12 may transmit a command CMDb to the memory device 11 through the second channel CH1 while transmitting the command CMDa to the memory device 11 through the first channel CH0. For example, the controller 12 may receive the data DATAb from the memory device 11 through the second channel CH1 while receiving the data DATAa to the memory device 11 through the first channel CH0. For example, the controller 12 may transmit an address ADDRb to the memory device 11 through the second channel CH1 while transmitting the address ADDRa to the memory device 11 through the first channel CH0.

The controller 12 may also increase the parallelism of data access to nonvolatile memories, which are connected to ways assigned to each channel, through a way-interleaving technique. Specifically, the controller 12 may execute a command for a way, in parallel with an internal operation on another way, by temporally overlapping program, read, and erase operations with respect to different ways. This may increase the use efficiency of a single channel, overall throughput, and I/O performance. For example, while the nonvolatile memory NVM11 connected to the way WAY11 is performing a program operation or a read operation, the controller 12 may transmit the command CMDa, the address ADDRa, and the data DATAa to the nonvolatile memory NVM12 connected to the way WAY12 through the first channel CH0 or may receive the data DATAa from the nonvolatile memory NVM12 through the first channel CH0.

According to the present embodiment, the memory device 11 may include a vertical nonvolatile memory device including vertically stacked memory chips. In an embodiment, at least two of the vertically stacked memory chips may be connected to the same channel such that the way-interleaving technique described above may be applied to the memory device 11. Various arrangements of memory chips for applying the way-interleaving technique to a vertical nonvolatile memory device are described below.

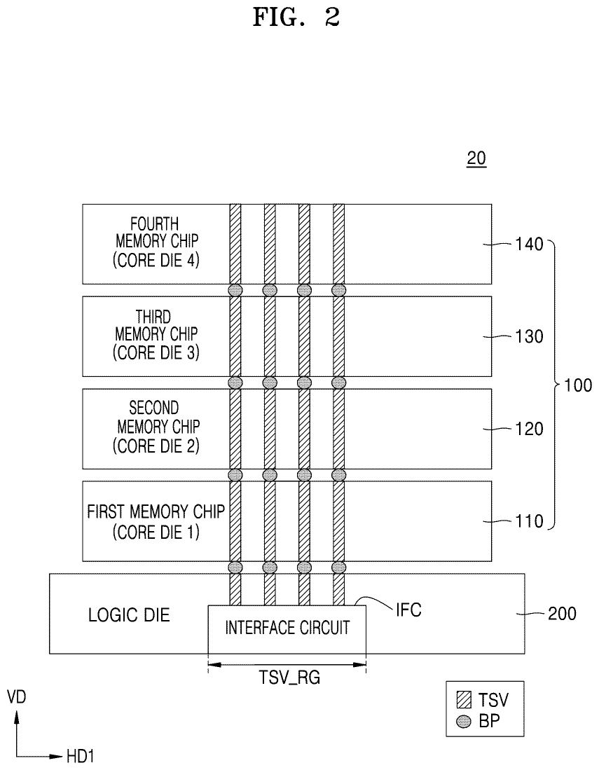

FIG. 2 schematically illustrates the structure of a memory device 20, according to an embodiment.

Referring to FIG. 2, the memory device 20 may include a logic die 200 and a memory die 100. According to an embodiment, the logic die 200 may be referred to as a base die. The memory die 100 may include first, second, third, and fourth core dies or first, second, third, and fourth memory chips 110, 120, 130, and 140, which are stacked on the logic die 200 in a vertical direction VD. According to an embodiment, the memory device 20 may be referred to as a three-dimensional (3D) memory device, a stacked memory device, or a vertical memory device.

For example, the memory device 20 may correspond to a 3D high-bandwidth flash (HBF) device. The memory device 20 may correspond to an example implementation of the memory device 11 in FIG. 1 or the storage device 10 of FIG. 1, and the descriptions given above with reference to FIG. 1 may also be applied to the present embodiment. For example, the first, second, third, and fourth memory chips 110, 120, 130, and 140 may respectively correspond to the nonvolatile memories NVM11 , NVM12 to NVM1n in FIG. 1.

The logic die 200 and the first, second, third, and fourth memory chips 110, 120, 130, and 140 may each include TSVs (illustrated as cross-hatched portions of FIG. 2). The TSVs of the logic die 200 may extend in the vertical direction VD through the logic die 200. The TSVs of each of the first, second, third, and fourth memory chips 110, 120, 130, and 140 may extend in the vertical direction VD through each of the first, second, third, and fourth memory chips 110, 120, 130, and 140. Bumps BP (illustrated as shaded portions of FIG. 2) may be arranged among the logic die 200 and the first, second, third, and fourth memory chips 110, 120, 130, and 140. For example, the bumps BP may correspond to microbumps. For example, the bumps BP may each include a conductive bump including copper, cobalt, or nickel. The logic die 200 and the first, second, third, and fourth memory chips 110, 120, 130, and 140 may be electrically connected to each other through the TSVs and the bumps BP.

The logic die 200 may further include an interface circuit IFC. The TSVs of the logic die 200 may be arranged in a TSV zone TSV_RG, and the interface circuit IFC may be connected to the TSVs in the TSV zone TSV_RG. For example, the interface circuit IFC may be arranged below the TSVs in the TSV zone TSV_RG and may thus be electrically connected to the first, second, third, and fourth memory chips 110, 120, 130, and 140 through the TSVs. However, the disclosure is not limited thereto. The interface circuit IFC may be arranged outside the TSV zone TSV_RG and connected to the TSVs of the logic die 200 through a redistribution line (not shown).

In an embodiment, a controller (e.g., the controller 12 in FIG. 1) that controls the memory die 100 may be implemented as a chip outside the logic die 200. For example, the logic die 200 and the controller may be arranged on an interposer and electrically connected to each other. However, the disclosure is not limited thereto. In some embodiments, the controller may be arranged inside the logic die 200.

In an embodiment, the first and third memory chips 110 and 130 may be connected to the first channel CH0, and the second and fourth memory chips 120 and 140 may be connected to the second channel CH1 such that the memory device 20 may be implemented in a 2-channel 2-way structure. In an embodiment, the first, second, third, and fourth memory chips 110, 120, 130, and 140 may be connected to the first channel CH0 such that the memory device 20 may be implemented in a 1-channel 4-way structure. In some embodiments, a plurality of memory chips may be further stacked on the fourth memory chip 140. For example, the memory device 20 may include twelve vertically stacked memory chips. However, the disclosure is not limited thereto.

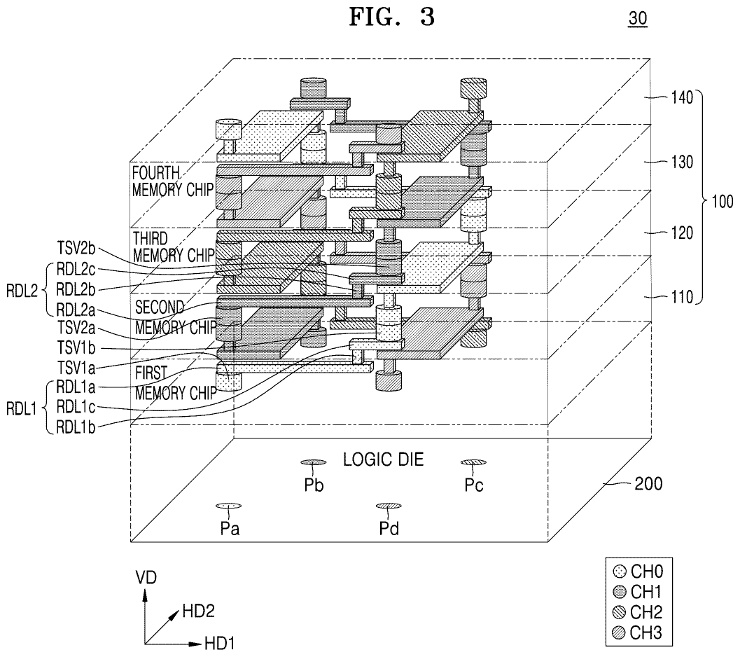

FIG. 3 is a perspective view of a memory device 30 according to an embodiment.

Referring to FIG. 3, the memory device 30 may correspond to a part of the memory device 20 of FIG. 2. For example, the logic die 200 may include first, second, third, and fourth I/O terminals Pa, Pb, Pc, and Pd respectively corresponding to first, second, third, and fourth channels CH0, CH1, CH2, and CH3. For example, the first, second, third, and fourth I/O terminals Pa, Pb, Pc, and Pd may correspond to DQ0terminals, DQ0 pins, DQ0 bumps, or DQ0 TSVs. I/O terminals of the memory die 100, which are connected to the first, second, third, and fourth I/O terminals Pa, Pb, Pc, and Pd, may be implemented in a spiral I/O structure including a spiral routing structure, as shown in FIG. 3. The spiral I/O structure may enable point-to-point connection, thereby optimizing power and speed for I/O.

Each of the first, second, third, and fourth memory chips 110, 120, 130, and 140 may include a plurality of I/O pins (e.g., TSVs), which respectively correspond to the first, second, third, and fourth I/O terminals Pa, Pb, Pc, and Pd, and a plurality of redistribution layers, which are connected to the I/O pins so as to implement a spiral routing stack. In an embodiment, the “spiral routing stack” may be regarded as a concept that includes a plurality of redistribution layers in each chip. In an embodiment, the “spiral routing stack” may be regarded as a concept that includes a plurality of redistribution layers and a plurality of TSVs in each chip. In an embodiment, the “spiral routing structure” may be regarded as a concept that includes both a plurality of redistribution layers and a plurality of TSVs, which connect a plurality of vertically stacked memory chips to each other. As described above, the spiral routing stack or the spiral routing structure may refer to a structure including redistribution layers arranged in a spiral shape.

For example, the first memory chip 110 may include a plurality of first through silicon vias TSV1a and TSV1b, which correspond to one of the first, second, third, and fourth channels CH0, CH1, CH2, and CH3 and extend in the vertical direction VD, and a plurality of first redistribution layers RDL1a, RDL1b, and RDL1c, which are connected to the first through silicon vias TSV1a and TSV1b so as to implement a first spiral routing stack RDL1. For example, the second memory chip 120 may include a plurality of second through silicon vias TSV2a and TSV2b, which correspond to one of the first, second, third, and fourth channels CH0, CH1, CH2, and CH3 and extend in the vertical direction VD, and a plurality of second redistribution layers RDL2a, RDL2b, and RDL2c, which are connected to the second through silicon vias TSV2a and TSV2b so as to implement a second spiral routing stack RDL2.

In an embodiment, the first spiral routing stack RDL1 and the second spiral routing stack RDL2 may be connected to each other through the second through silicon via TSV2a. In an embodiment, the first spiral routing stack RDL1 and the second spiral routing stack RDL2 may be connected to each other through the first through silicon via TSV1b and the second through silicon via TSV2a. The descriptions of the first and second spiral routing stacks RDL1 and RDL2 of the first and second memory chips 110 and 120 may also be applied to the third and fourth memory chips 130 and 140 in a similar manner.

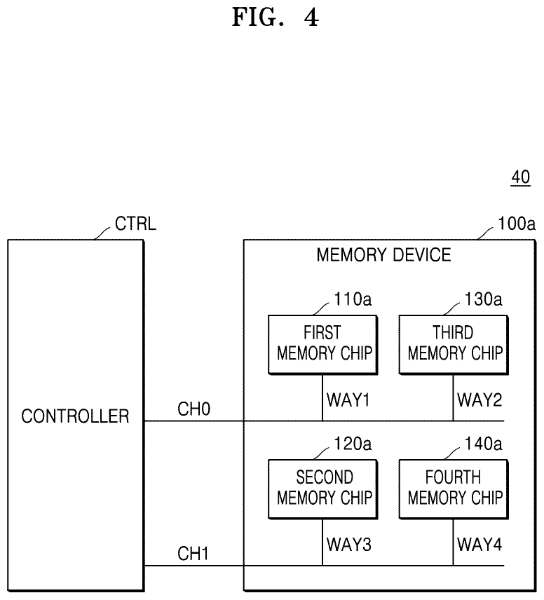

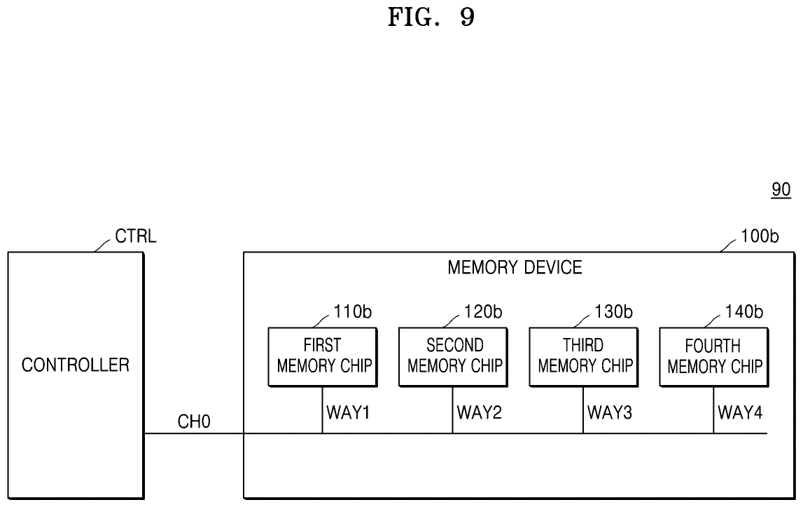

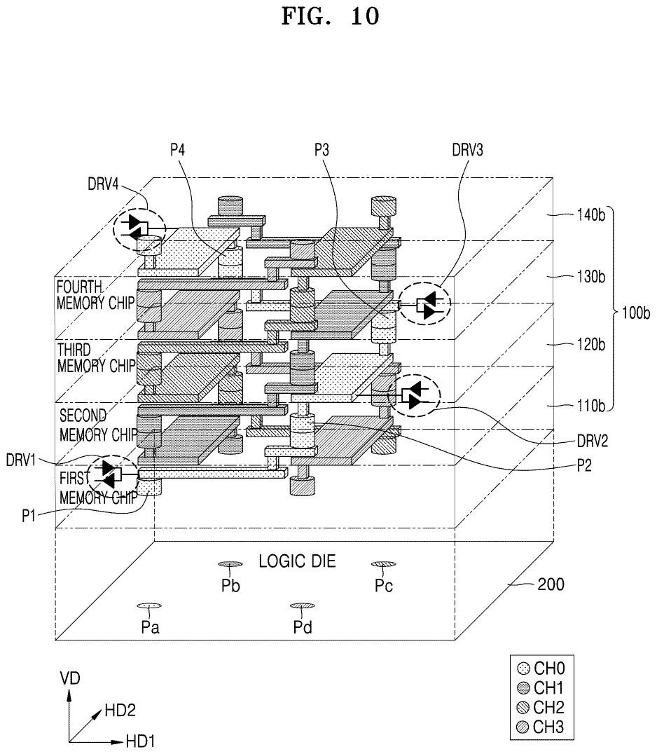

When each of the first, second, third, and fourth memory chips 110, 120, 130, and 140 includes flash memory cells, a way-interleaving technique may be used by connecting a plurality of memory chips to one channel, e.g., the first channel CH0,among the first, second, third, and fourth channels CH0, CH1, CH2, and CH3. For example, a 2-channel 2-way structure may be implemented by connecting the first I/O terminal Pa corresponding to the first channel CH0 to the first and third memory chips 110 and 130 and connecting the second I/O terminal Pb corresponding to the second channel CH1 to the second and fourth memory chips 120 and 140, which is described with reference to FIGS. 4 to 8 below. For example, a 1-channel 4-way structure may be implemented by connecting the first I/O terminal Pa corresponding to the first channel CH0 to the first, second, third, and fourth memory chips 110 to 140, which is described with reference to FIGS. 9 to 12 below.

FIG. 4 is a block diagram of a storage device 40 according to an embodiment.

Referring to FIG. 4, the storage device 40 may include a memory device 100a and a controller CTRL, thereby having a 2-channel 2-way structure. The controller CTRL may be connected to first and third memory chips 110a and 130a through the first channel CH0, the first memory chip 110a may be connected to a way WAY1, and the third memory chip 130a may be connected to a way WAY2. The controller CTRL may also be connected to second and fourth memory chips 120a and 140a through the second channel CH1, the second memory chip 120a may be connected to a way WAY3, and the fourth memory chip 140a may be connected to a way WAY4.

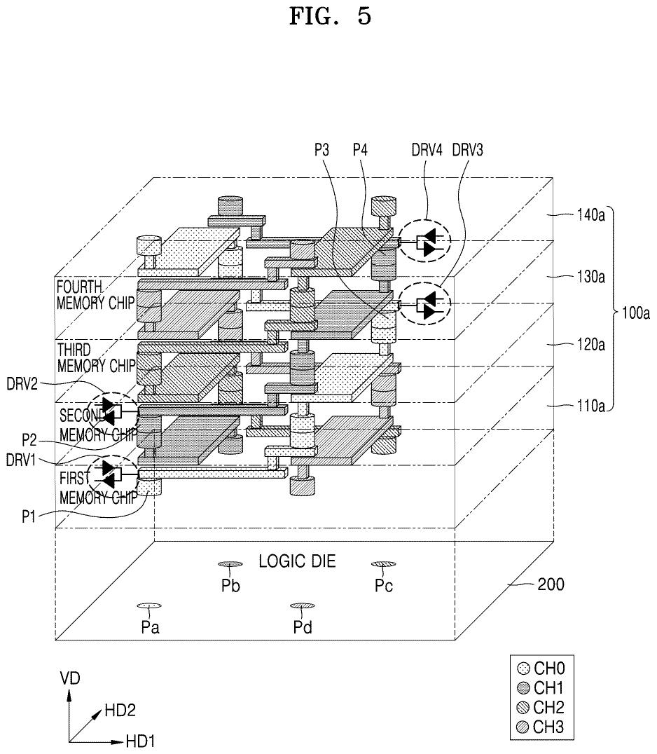

FIG. 5 is a perspective view of the memory device 100a in FIG. 4, according to an embodiment.

Referring to FIG. 5, the first, second, third, and fourth memory chips 110a, 120a, 130a, and 140a may be sequentially stacked on a logic die 200 in the vertical direction VD. For example, the third and fourth memory chips 130a and 140a may be stacked with a 180-degree rotation relative to the first and second memory chips 110a and 120a. The logic die 200 may include the first, second, third, and fourth I/O terminals Pa, Pb, Pc, and Pd. According to the present embodiment, a 2-channel 2-way structure may be implemented by connecting the first I/O terminal Pa corresponding to the first channel CH0 to the first and third memory chips 110a and 130a and connecting the second I/O terminal Pb corresponding to the second channel CH1 to the second and fourth memory chips 120a and 140a. The memory device 100a may correspond to an example implementation of the memory device 30, and the descriptions given above with reference to FIGS. 1 to 3 may also be applied to the present embodiment.

The first memory chip 110a may include a first I/O circuit DRV1 and a first pin P1 connected to the first I/O circuit DRV1. The first pin P1 may be electrically connected to the first I/O terminal Pa such that the first memory chip 110a may communicate with the first channel CH0. For example, the first pin P1 may correspond to a TSV that passes through the first memory chip 110a in the vertical direction VD. In an embodiment, the first I/O circuit DRV1 may be connected to the first pin P1 through a redistribution layer. However, the disclosure is not limited thereto. The first I/O circuit DRV1 may be directly connected to the first pin P1. In this case, the first I/O circuit DRV1 and the first pin P1 may be arranged in a first region of the first memory chip 110a.

The second memory chip 120a may include a second I/O circuit DRV2 and a second pin P2 connected to the second I/O circuit DRV2. The second pin P2 may be electrically connected to the second I/O terminal Pb such that the second memory chip 120a may communicate with the second channel CH1. For example, the second pin P2 may correspond to a TSV that passes through the second memory chip 120a in the vertical direction VD. In an embodiment, the second I/O circuit DRV2 may be connected to the second pin P2 through a redistribution layer. However, the disclosure is not limited thereto. The second I/O circuit DRV2 may be directly connected to the second pin P2. In this case, the second I/O circuit DRV2 and the second pin P2 may be arranged in a second region of the second memory chip 120a. The second region of the second memory chip 120a may overlap the first region of the first memory chip 110a in the vertical direction VD.

The third memory chip 130a may include a third I/O circuit DRV3 and a third pin P3 connected to the third I/O circuit DRV3. The third pin P3 may be electrically connected to the first I/O terminal Pa such that the third memory chip 130a may communicate with the first channel CH0. For example, the third pin P3 may correspond to a TSV that passes through the third memory chip 130a in the vertical direction VD. In an embodiment, the third I/O circuit DRV3 may be connected to the third pin P3 through a redistribution layer. However, the disclosure is not limited thereto. The third I/O circuit DRV3 may be directly connected to the third pin P3.

In this case, the third I/O circuit DRV3 and the third pin P3 may be arranged in a third region of the third memory chip 130a. The third region of the third memory chip 130a may have a 180-degree rotation in a horizontal direction, e.g., a first direction HD1 or a second direction HD2, relative to the first region of the first memory chip 110a and the second region of the second memory chip 120a. The term “horizontal direction” used herein may refer to the first direction HD1 or the second direction HD2. According to an embodiment, the horizontal direction may be referred to as a planar direction.

The fourth memory chip 140a may include a fourth I/O circuit DRV4 and a fourth pin P4 connected to the fourth I/O circuit DRV4. The fourth pin P4 may be electrically connected to the second I/O terminal Pb such that the fourth memory chip 140a may communicate with the second channel CH1. For example, the fourth pin P4 may correspond to a TSV that passes through the fourth memory chip 140a in the vertical direction VD. In an embodiment, the fourth I/O circuit DRV4 may be connected to the fourth pin P4 through a redistribution layer. However, the disclosure is not limited thereto. The fourth I/O circuit DRV4 may be directly connected to the fourth pin P4.

In this case, the fourth I/O circuit DRV4 and the fourth pin P4 may be arranged in a fourth region of the fourth memory chip 140a. The fourth region of the fourth memory chip 140a may overlap the third region of the third memory chip 130a in the vertical direction VD. The fourth region of the fourth memory chip 140a may have a 180-degree rotation in the horizontal direction, e.g., the first direction HD1 or the second direction HD2, relative to the first region of the first memory chip 110a and the second region of the second memory chip 120a.

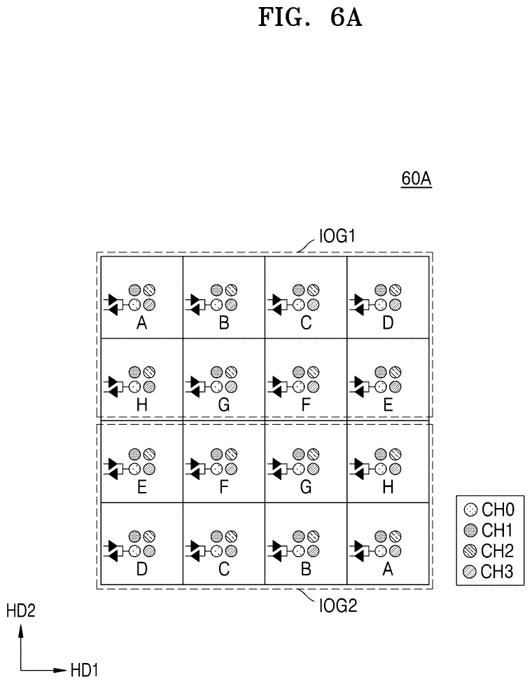

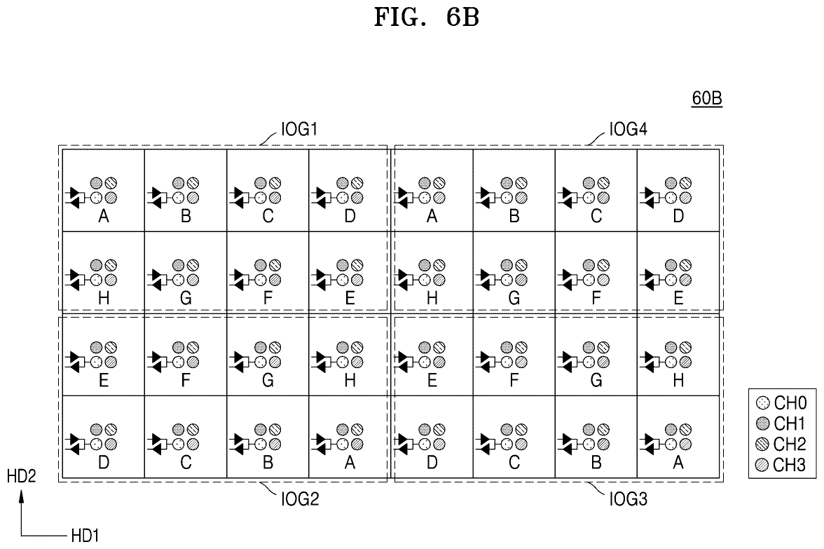

FIG. 6A illustrates an I/O array 60A according to an embodiment.

Referring to FIG. 6A, the I/O array 60A may correspond to, for example, one of the first, second, third, and fourth memory chips 110a, 120a, 130a, and 140a in FIG. 4. The I/O array 60A may include first and second I/O groups IOG1 and IOG2. According to an embodiment, an “I/O array” may be referred to as an “I/O pin array” or a “pin array”, and an “I/O group” may be referred to as an “I/O pin group” or a “pin group”. For example, the first and second I/O groups IOG1 and IOG2 may respectively correspond to first and second memory array tiles (MATs) of a memory chip. According to an embodiment, an MAT may be referred to as a plane and may correspond to a unit capable of independently performing a memory operation.

Each of the first and second I/O groups IOG1 and IOG2 may include a plurality of spiral I/O units or a plurality of I/O units. For example, the first I/O group IOG1 may include I/O units A, B, C, D, E, F, G, and H respectively corresponding to DQ0, DQ1,DQ2, DQ3, DQ4, DQ5, DQ6, and DQ7, and each of the I/O units A, B, C, D, E, F, G, and H may include pins or TSVs respectively corresponding to the first, second, third, and fourth channels CH0, CH1, CH2, and CH3. Similarly, the second I/O group IOG2 may include the I/O units A, B, C, D, E, F, G, and H respectively corresponding to DQ0,DQ1, DQ2, DQ3, DQ4, DQ5, DQ6, and DQ7, and each of the I/O units A, B, C, D, E, F, G, and H may include pins or TSVs respectively corresponding to the first, second, third, and fourth channels CH0, CH1, CH2, and CH3. For example, the first and second I/O groups IOG1 and IOG2 may have a 180-degree rotation in the horizontal direction, e.g., the first direction HD1 or the second direction HD2, relative to each other.

FIG. 6B illustrates an I/O array 60B according to an embodiment.

Referring to FIG. 6B, the I/O array 60B may correspond to, for example, one of the first, second, third, and fourth memory chips 110a, 120a, 130a, and 140a in FIG. 4. The I/O array 60B may include first, second, third, and fourth I/O groups IOG1, IOG2, IOG3, and IOG4. For example, the first, second, third, and fourth I/O groups IOG1, IOG2, IOG3, and IOG4 may respectively correspond to first, second, third, and fourth MATs of a memory chip. Each of the first, second, third, and fourth I/O groups IOG1 to IOG4 may include a plurality of spiral I/O units or a plurality of I/O units. For example, the first I/O group IOG1 may include the I/O units A, B, C, D, E, F, G, and H respectively corresponding to DQ0, DQ1, DQ2, DQ3, DQ4, DQ5, DQ6, and DQ7, and each of the I/O units A, B, C, D, E, F, G, and H may include pins or TSVs respectively corresponding to the first, second, third, and fourth channels CH0, CH1, CH2, and CH3. For example, the third and fourth I/O groups IOG3 and IOG4 may have a 180-degree rotation in the horizontal direction, e.g., the first direction HD1 or the second direction HD2, relative to each other.

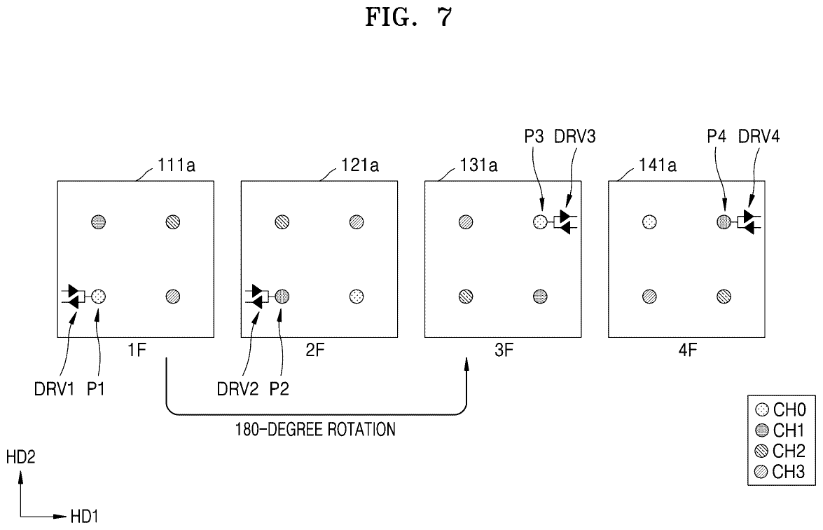

FIG. 7 illustrates I/O units 111a, 121a, 131a, and 141a according to an embodiment.

Referring to FIGS. 5 and 7, the I/O unit 111a may be included in the I/O array, I/O group, or pin group of the first memory chip 110a in a first floor 1F, the I/O unit 121a may be included in the I/O array, I/O group, or pin group of the second memory chip 120a in a second floor 2F, the I/O unit 131a may be included in the I/O array, I/O group, or pin group of the third memory chip 130a in a third floor 3F, and the I/O unit 141a may be included in the I/O array, I/O group, or pin group of the fourth memory chip 140a in a fourth floor 4F.

As described above, the I/O units 111a, 121a, 131a and 141a may overlap each other in the vertical direction VD and may be electrically connected to each other through a spiral I/O structure or a spiral routing structure. For example, the I/O units 111a, 121a, 131a, and 141a may correspond to DQ0. For example, the I/O unit 111a may correspond to the I/O unit A in the first I/O group IOG1 in FIG. 6A.

According to the present embodiment, redistribution lines may be arranged in a spiral I/O structure considering the number of channels supported by a memory device, and I/O units may be grouped considering the rotation angles of memory chips. An arrangement when the first, second, third, and fourth memory chips 110a, 120a, 130a, and 140a are connected to two channels, i.e., the first and second channels CH0 and CH1, is described below. When the first, second, third, and fourth memory chips 110a, 120a, 130a, and 140a are connected to the first and second channels CH0 and CH1, at least one of the first, second, third, and fourth memory chips 110a, 120a, 130a, and 140a may be stacked with a 180-degree rotation in the horizontal direction, e.g., the first direction HD1 or the second direction HD2.

The first and second memory chips 110a and 120a respectively connected to the first and second channels CH0 and CH1 may be stacked in the vertical direction VD. The first memory chip 110a may include the first pin P1 and the first I/O circuit DRV1. For example, the first pin P1 may correspond to DQ0 of the first channel CH0. The second memory chip 120a may include the second pin P2 and the second I/O circuit DRV2. For example, the second pin P2 may correspond to DQ0 of the second channel CH1. The first pin P1 and the first I/O circuit DRV1 may be arranged in the first region of the first memory chip 110a, the second pin P2 and the second I/O circuit DRV2 may be arranged in the second region of the second memory chip 120a, and the first and second regions may overlap each other in the vertical direction VD.

The third and fourth memory chips 130a and 140a respectively connected to the first and second channels CH0 and CH1 may be stacked in the vertical direction VD. The third and fourth memory chips 130a and 140a may be stacked with a 180-degree rotation in the first direction HD1 or the second direction HD2, relative to the first and second memory chips 110a and 120a. The third memory chip 130a may include the third pin P3 and the third I/O circuit DRV3. For example, the third pin P3 may correspond to DQ0 of the first channel CH0.

The fourth memory chip 140a may include the fourth pin P4 and the fourth I/O circuit DRV4. For example, the fourth pin P4 may correspond to DQ0 of the second channel CH1. The third pin P3 and the third I/O circuit DRV3 may be arranged in the third region of the third memory chip 130a, the fourth pin P4 and the fourth I/O circuit DRV4 may be arranged in the fourth region of the fourth memory chip 140a, and the third and fourth regions may overlap each other in the vertical direction VD. The first and second regions may not overlap the third and fourth regions.

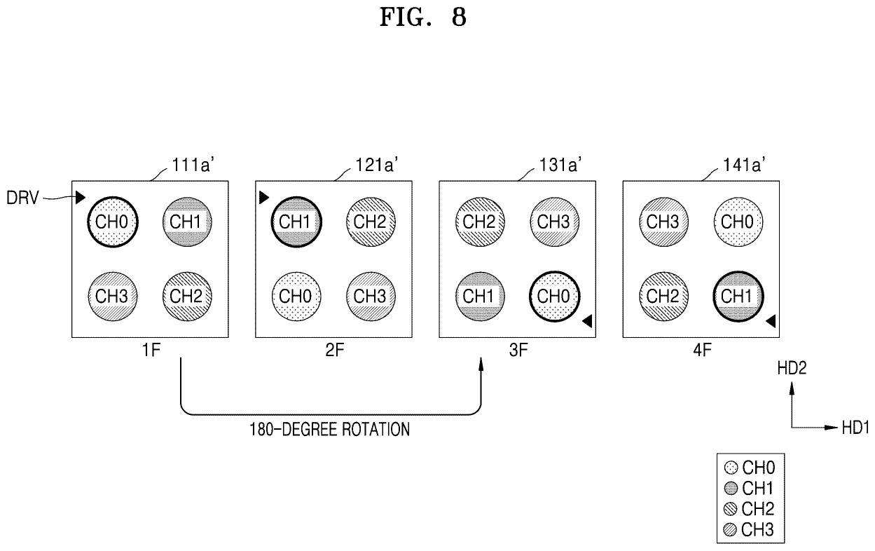

FIG. 8 illustrates I/O units 111a′, 121a′, 131a′, and 141a′ according to an embodiment.

Referring to FIG. 8, the I/O units 111a′, 121a′, 131a′, and 141a′ may correspond to an example modification of the I/O units 111a, 121a, 131a, and 141a in FIG. 7, and the descriptions given with reference to FIG. 7 may also be applied to the present embodiment. Each of the I/O units 111a′, 121a′, 131a′, and 141a′ include a respective driver DRV. The driver DRV of the I/O unit 111a′ may be connected to the first channel CH0, the driver DRV of the I/O unit 121a′ may be connected to the second channel CH1, and the positions of the drivers DRV of the I/O units 111a′ and 121a′ may overlap each other in the vertical direction VD. The I/O units 131a′ and 141a′ may be stacked with a 180-degree rotation in the first direction HD1 or the second direction HD2. The driver DRV of the I/O unit 131a′ may be connected to the first channel CH0, the driver DRV of the I/O unit 141a′ may be connected to the second channel CH1, and the positions of the drivers DRV of the I/O units 131a′ and 141a′ may overlap each other in the vertical direction VD.

FIG. 9 is a block diagram of a storage device 90 according to an embodiment.

Referring to FIG. 9, the storage device 90 may include a memory device 100b and the controller CTRL, thereby having a 1-channel 4-way structure. The controller CTRL may be connected to first, second, third, and fourth memory chips 110b, 120b, 130b, and 140b through the first channel CH0. The first memory chip 110b may be connected to the way WAY1, the second memory chip 120b may be connected to the way WAY2, the third memory chip 130b may be connected to the way WAY3, and the fourth memory chip 140b may be connected to the way WAY4.

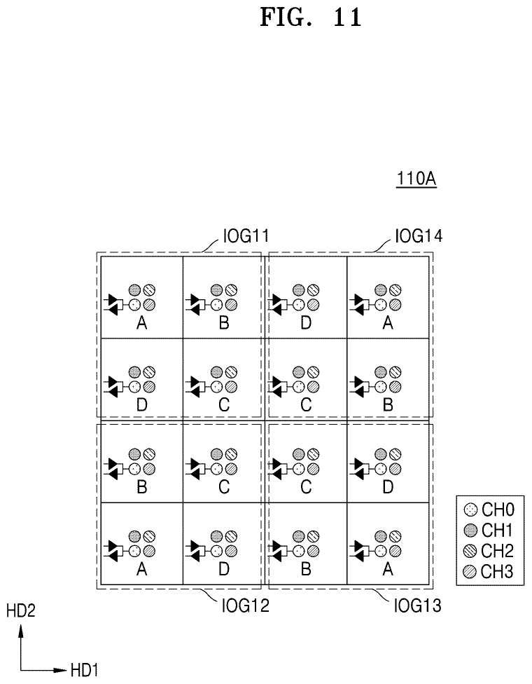

FIG. 10 is a perspective view of the memory device 100b in FIG. 9, according to an embodiment.

Referring to FIG. 10, the first, second, third, and fourth memory chips 110b, 120b, 130, and 140b may be sequentially stacked on the logic die 200 in the vertical direction VD. For example, the second memory chip 120b may be stacked with a 90-degree rotation relative to the first memory chip 110b, the third memory chip 130b may be stacked with a 90-degree rotation relative to the second memory chip 120b, and the fourth memory chip 140b may be stacked with a 90-degree rotation relative to the third memory chip 130b. The logic die 200 may include the first, second, third, and fourth I/O terminals Pa, Pb, Pc, and Pd. According to the present embodiment, a 1-channel 4-way structure may be implemented by connecting the first I/O terminal Pa corresponding to the first channel CH0 to the first, second, third, and fourth memory chips 110b, 120b, 130b, and 140b.

The first memory chip 110b may include the first I/O circuit DRV1 and the first pin P1 connected to the first I/O circuit DRV1. The first pin P1 may be electrically connected to the first I/O terminal Pa such that the first memory chip 110b may communicate with the first channel CH0. For example, the first pin P1 may correspond to a TSV that passes through the first memory chip 110b in the vertical direction VD. In this case, the first I/O circuit DRV1 and the first pin P1 may be arranged in a first region of the first memory chip 110b.

The second memory chip 120b may include the second I/O circuit DRV2 and the second pin P2 connected to the second I/O circuit DRV2. The second pin P2 may be electrically connected to the first I/O terminal Pa such that the second memory chip 120b may communicate with the first channel CH0. For example, the second pin P2 may correspond to a TSV that passes through the second memory chip 120b in the vertical direction VD. In this case, the second I/O circuit DRV2 and the second pin P2 may be arranged in a second region of the second memory chip 120b. The second region of the second memory chip 120b may correspond to a position to which the first region of the first memory chip 110b is rotated by 90 degrees in the first direction HD1 or the second direction HD2.

The third memory chip 130b may include the third I/O circuit DRV3 and the third pin P3 connected to the third I/O circuit DRV3. The third pin P3 may be electrically connected to the first I/O terminal Pa such that the third memory chip 130b may communicate with the first channel CH0. For example, the third pin P3 may correspond to a TSV that passes through the third memory chip 130b in the vertical direction VD. In this case, the third I/O circuit DRV3 and the third pin P3 may be arranged in a third region of the third memory chip 130b. The third region of the third memory chip 130b may correspond to a position to which the second region of the second memory chip 120b is rotated by 90 degrees in the first direction HD1 or the second direction HD2.

The fourth memory chip 140b may include the fourth I/O circuit DRV4 and the fourth pin P4 connected to the fourth I/O circuit DRV4. The fourth pin P4 may be electrically connected to the first I/O terminal Pa such that the fourth memory chip 140b may communicate with the first channel CH0. For example, the fourth pin P4 may correspond to a TSV that passes through the fourth memory chip 140b in the vertical direction VD. In this case, the fourth I/O circuit DRV4 and the fourth pin P4 may be arranged in a fourth region of the fourth memory chip 140b. The fourth region of the third memory chip 140b may correspond to a position to which the third region of the third memory chip 130b is rotated by 90 degrees in the first direction HD1 or the second direction HD2.

FIG. 11 illustrates an I/O array 110A according to an embodiment.

Referring to FIG. 11, the I/O array 110A may correspond to, for example, one of the first, second, third, and fourth memory chips 110b, 120b, 130b, and 140b in FIG. 9. The I/O array 110A may include first, second, third, and fourth I/O groups IOG11, IOG12, IOG13, and IOG14. In an embodiment, the first and fourth I/O groups IOG11 and IOG14 may correspond to a first MAT of a memory chip, and the second and third I/O groups IOG12 and IOG13 may correspond to a second MAT of the memory chip. In an embodiment, the first, second, third, and fourth I/O groups IOG11, IOG12, IOG13, and IOG14 may respectively correspond to first, second, third, and fourth MATs of a memory chip.

Each of the first, second, third, and fourth I/O groups IOG11, IOG12, IOG13, and IOG14 may include a plurality of spiral I/O units or a plurality of I/O units. For example, the first I/O group IOG11 may include the I/O units A, B, C, and D respectively corresponding to DQ0, DQ1, DQ2, and DQ3, and each of the I/O units A, B, C, and D may include pins or TSVs respectively corresponding to the first, second, third, and fourth channels CH0, CH1, CH2, and CH3. Similarly, the second I/O group IOG12 may include the I/O units A, B, C, and D respectively corresponding to DQ0, DQ1, DQ2, and DQ3, and each of the I/O units A, B, C, and D may include pins or TSVs respectively corresponding to the first, second, third, and fourth channels CH0, CH1, CH2, and CH3.For example, the first and second I/O groups IOG11 and IOG12 may be arranged with a 90-degree rotation in the horizontal direction, e.g., the first direction HD1 or the second direction HD2, relative to each other. For example, the third and fourth I/O groups IOG13 and IOG14 may be arranged with a 90-degree rotation in the horizontal direction, e.g., the first direction HD1 or the second direction HD2, relative to each other.

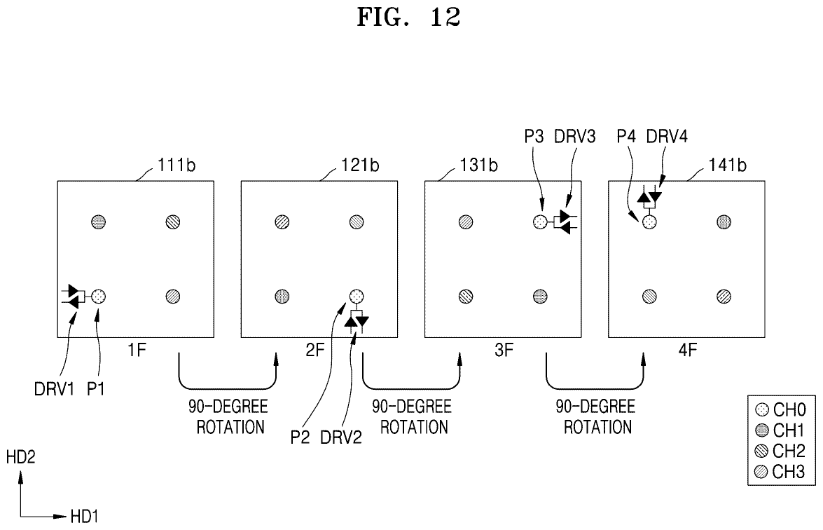

FIG. 12 illustrates I/O units 111b, 121b, 131b, and 141b according to an embodiment.

Referring to FIGS. 10 and 12, the I/O unit 111b may be included in the I/O array, I/O group, or pin group of the first memory chip 110b in the first floor 1F, the I/O unit 121b may be included in the I/O array, I/O group, or pin group of the second memory chip 120b in the second floor 2F, the I/O unit 131b may be included in the I/O array, I/O group, or pin group of the third memory chip 130b in the third floor 3F, and the I/O unit 141b may be included in the I/O array, I/O group, or pin group of the fourth memory chip 140b in the fourth floor 4F.

As described above, the I/O units 111b, 121b, 131b, and 141b may overlap each other in the vertical direction VD and may be electrically connected to each other through a spiral I/O structure or a spiral routing structure. For example, the I/O units 111b, 121b, 131b, and 141b may correspond to DQ0. For example, the I/O unit 111b may correspond to the I/O unit A in the first I/O group IOG11 in FIG. 11.

According to the present embodiment, redistribution lines may be arranged in a spiral I/O structure considering the number of channels supported by a memory device, and I/O units may be grouped considering the rotation angles of memory chips. An arrangement when the first, second, third, and fourth memory chips 110b, 120b, 130b, and 140b are connected to one channel, i.e., the first channel CH0, is described below. When the first, second, third, and fourth memory chips 110b, 120b, 130b, and 140b are connected to the first channel CH0, at least one of the first, second, third, and fourth memory chips 110b, 120b, 130b, and 140b may be stacked with a 90-degree rotation in the horizontal direction, e.g., the first direction HD1 or the second direction HD2.

The first, second, third, and fourth memory chips 110b, 120b, 130b, and 140b connected to the first channel CH0 may be stacked in the vertical direction VD, with a 90-degree rotation. Specifically, the second memory chip 120b may be stacked with a 90-degree rotation relative to the first memory chip 110b, the third memory chip 130b may be stacked with a 90-degree rotation relative to the second memory chip 120b, and the fourth memory chip 140b may be stacked with a 90-degree rotation relative to the third memory chip 130b.

The first memory chip 110b may include the first pin P1 and the first I/O circuit DRV1. For example, the first pin P1 may correspond to DQ0 of the first channel CH0. The second memory chip 120b may include the second pin P2 and the second I/O circuit DRV2. For example, the second pin P2 may correspond to DQ0 of the first channel CH0. The first pin P1 and the first I/O circuit DRV1 may be arranged in the first region of the first memory chip 110b, the second pin P2 and the second I/O circuit DRV2 may be arranged in the second region of the second memory chip 120b, and the first and second regions may not overlap each other in the vertical direction VD. For example, the second region may have a 90-degree rotation relative to the first region.

The third memory chip 130b may include the third pin P3 and the third I/O circuit DRV3. For example, the third pin P3 may correspond to DQ0 of the first channel CH0. The fourth memory chip 140b may include the fourth pin P4 and the fourth I/O circuit DRV4. For example, the fourth pin P4 may correspond to DQ0 of the first channel CH0. The third pin P3 and the third I/O circuit DRV3 may be arranged in the third region of the third memory chip 130b, the fourth pin P4 and the fourth I/O circuit DRV4 may be arranged in the fourth region of the fourth memory chip 140b, and the third and fourth regions may not overlap each other in the vertical direction VD. For example, the fourth region may have a 90-degree rotation relative to the third region.

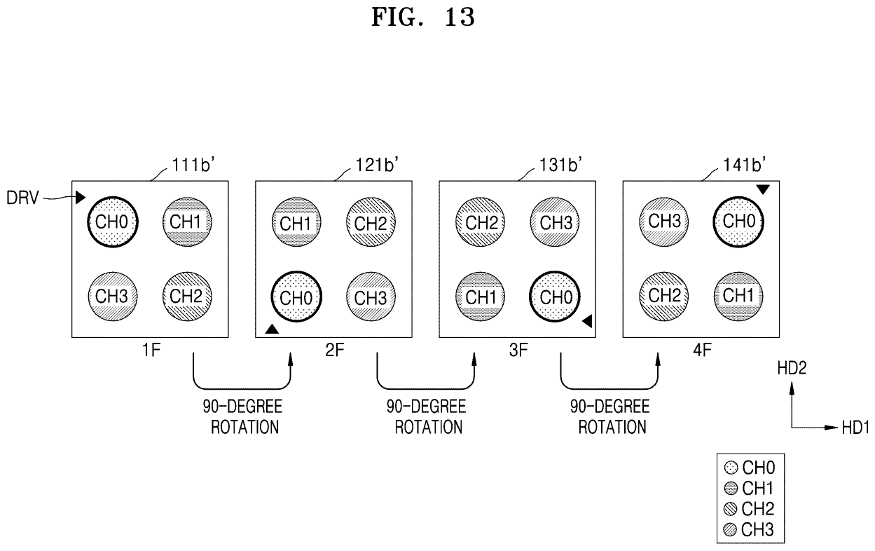

FIG. 13 illustrates I/O units 111b′, 121b′, 131b′, and 141b′ according to an embodiment.

Referring to FIG. 13, the I/O units 111b′, 121b′, 131b′, and 141b′ may correspond to an example modification of the I/O units 111b, 121b, 131b, and 141b in FIG. 12, and the descriptions given with reference to FIG. 12 may also be applied to the present embodiment. The driver DRV of each of the I/O units 111b′, 121b′, 131b′, and 141b′ may be connected to the first channel CH0, and the positions of the drivers DRV of the I/O units 111b′, 121b′, 131b′, and 141b′ may not overlap one another in the vertical direction VD. The I/O unit 121b′ may be stacked with a 90-degree rotation relative to the I/O unit 111b′, the I/O unit 131b′ may be stacked with a 90-degree rotation relative to the I/O unit 121b′, and the I/O unit 141b′ may be stacked with a 90-degree rotation relative to the I/O unit 131b′.

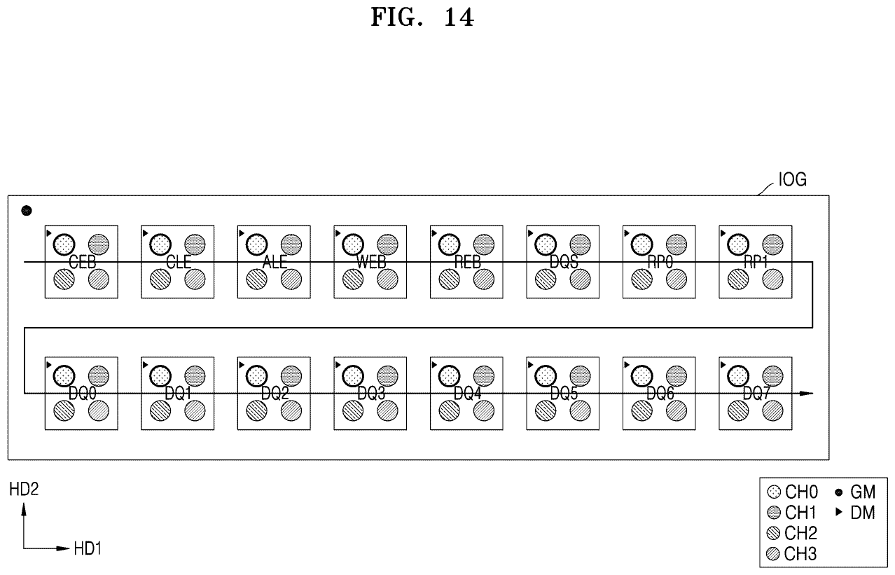

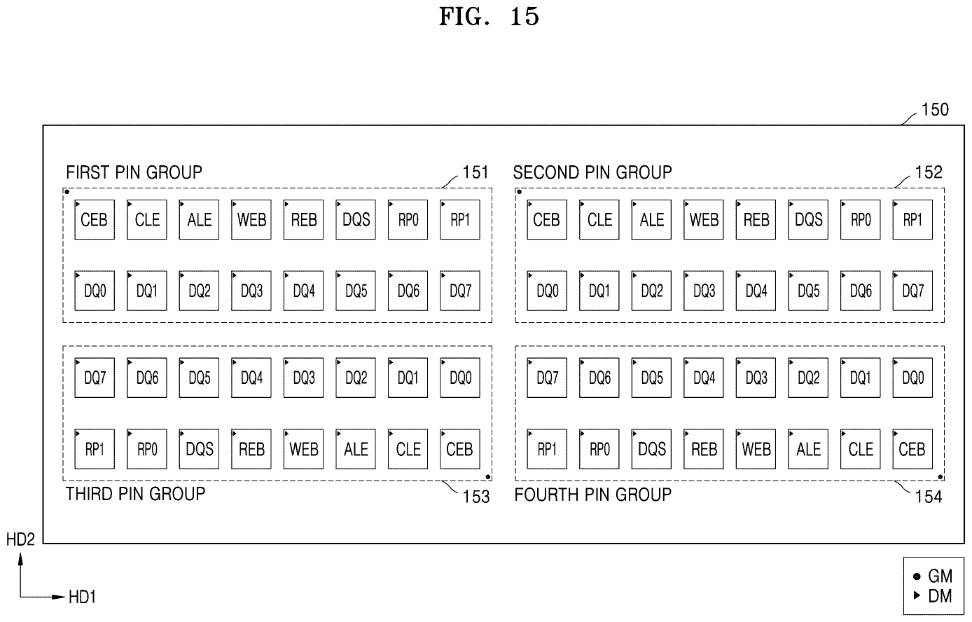

FIG. 14 illustrates an I/O group IOG according to an embodiment.

Referring to FIG. 14, the I/O group IOG may include a plurality of I/O units, and each of the I/O units may include TSVs respectively corresponding to a plurality of channels. TSVs included in each pin may be implemented in a spiral structure through redistribution lines. The I/O group IOG may be marked with a group mark GM, and each I/O unit may be marked with a driver mark DM indicating the arrangement of a driver. For example, the I/O group IOG may include pins connected to the first channel CH0, and accordingly, the driver mark DM may be displayed adjacent to the first channel CH0.

For example, the I/O group IOG may include I/O units respectively corresponding to 16 pins, which may respectively correspond to a chip enable bar signal CEB, a command latch enable signal CLE, an address latch enable signal ALE, a write enable bar signal WEB, a read enable bar signal REB, a data strobe signal DQS, reset signals RP0 and RP1, and data signals DQ0, DQ1, DQ3, DQ4, DQ5, DQ6, DQ7, and DQ7. For example, the chip enable bar signal CEB, the command latch enable signal CLE, the address latch enable signal ALE, the write enable bar signal WEB, the read enable bar signal REB, the data strobe signal DQS, and the reset signals RP0 and RP1 may be arranged in the first direction HD1, and the data signals DQ0, DQ1, DQ3, DQ4, DQ5,DQ6, and DQ7 may be arranged in the first direction HD1.

FIG. 15 illustrates a memory chip 150 according to an embodiment.

Referring to FIG. 15, the memory chip 150 may include first, second, third, and fourth pin groups 151, 152, 153, and 154. For example, each of the first, second, third, and fourth pin groups 151, 152, 153, and 154 may correspond to the I/O group IOG of FIG. 14. The first, second, third, and fourth pin groups 151, 152, 153, and 154 may be rotatably arranged. For example, the first, second, third, and fourth pin groups 151, 152, 153, and 154 may be arranged with a 180-degree rotation. For example, the third and fourth pin groups 153 and 154 may be arranged with a 180-degree rotation relative to the first and second pin groups 151 and 152, and a rotation angle may be identified by the group mark GM. For example, the memory chip 150 may correspond to one of the first, second, third, and fourth memory chips 110a, 120a, 130a, and 140a in FIG. 4 or one of the first, second, third, and fourth memory chips 110b, 120b, 130b, and 140b in FIG. 9. For example, the first, second, third, and fourth pin groups 151, 152, 153, and 154 may respectively correspond to first to fourth MATs.

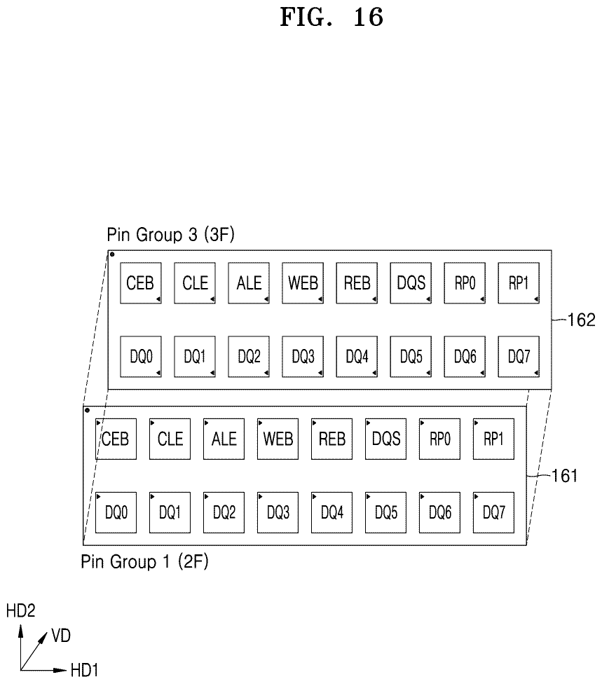

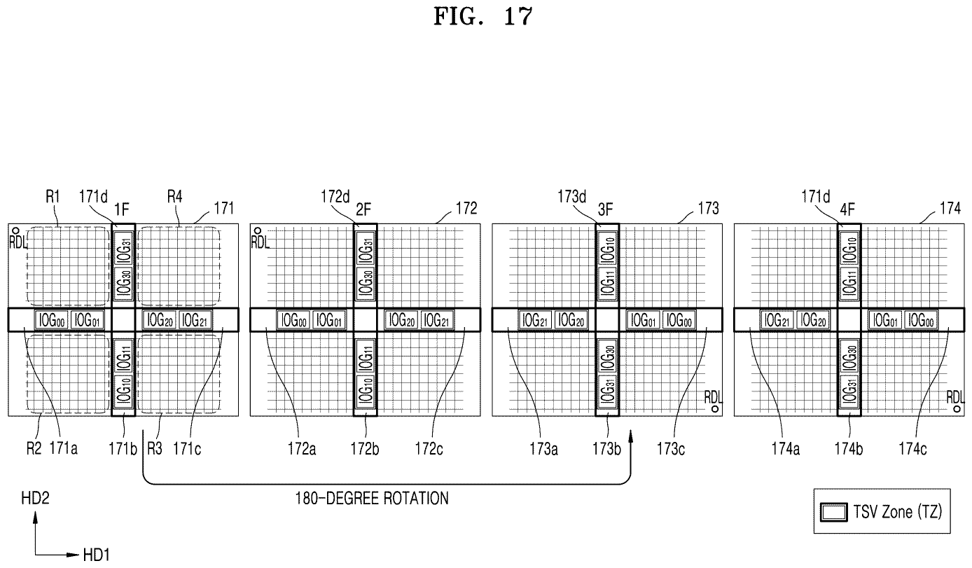

FIG. 16 illustrates an example of a vertical arrangement of pin groups 161 and 162, according to an embodiment.

Referring to FIG. 16, the pin group 161 may correspond to a first pin group of a second memory chip (e.g., the second memory chip 120a in FIG. 5) in the second floor 2F, the pin group 162 may correspond to a third pin group of a third memory chip (e.g., the third memory chip 130a in FIG. 5) in the third floor 3F. As described above, the third memory chip may be stacked with a 180-degree rotation relative to the second memory chip such that the first pin group of the second memory chip may overlap the third pin group of the third memory chip in the vertical direction VD.

FIG. 17 illustrates an example of an arrangement of first, second, third, and fourth memory chips 171, 172, 173, and 174, according to an embodiment.

Referring to FIG. 17, the first memory chip 171 may be arranged in the first floor 1F, the second memory chip 172 may be arranged in the second floor 2F, the third memory chip 173 may be arranged in the third floor 3F, and the fourth memory chip 174 may be arranged in the fourth floor 4F. The third and fourth memory chips 173 and 174 may be arranged with a 180-degree rotation relative to the first and second memory chips 171 and 172 such that the first, second, third, and fourth memory chips 171, 172, 173, and 174 may support a 2-channel 2-way structure.

Each of the first, second, third, and fourth memory chips 171, 172, 173, and 174 may have TSV zones TZ in which TSVs are arranged. For example, each of the first, second, third, and fourth memory chips 171, 172, 173, and 174 may be implemented in a rectangular shape. In each of the first, second, third, and fourth memory chips 171, 172, 173, and 174, the TSV zones TZ may be spaced apart from each other. Each of the first, second, third, and fourth memory chips 171, 172, 173, and 174 may include devices respectively connected to I/O groups, which are arranged in the TSV zones TZ, through redistribution patterns RDL.

The first memory chip 171 may include TSV zones 171a, 171b, 171c, and 171d. For example, the TSV zones 171a and 171c may be spaced apart from each other in the first direction HD1, and the TSV zones 171b and 171d may be spaced apart from each other in the second direction HD1. For example, the TSV zones 171a and 171c may be aligned with each other in the first direction HD1, and the TSV zones 171b and 171d may aligned with each other in the second direction HD2. However, the arrangement of the TSV zones 171a to 171d is not limited thereto and may vary with embodiments.

First I/O groups IOG₀₀ and IOG₀₁ may be arranged in the TSV zone 171a and may be connected to first redistribution patterns extending in the second direction HD2. Second I/O groups IOG₁₀ and IOG₁₁ may be arranged in the TSV zone 171b and may be connected to second redistribution patterns extending in the first direction HD1. Third I/O groups IOG₂₀ and IOG₂₁ may be arranged in the TSV zone 171c and may be connected to third redistribution patterns extending in the second direction HD2. Fourth I/O groups IOG₃₀ and IOG₃₁ may be arranged in the TSV zone 171d and may be connected to fourth redistribution patterns extending in the first direction HD1. For example, each of the first to fourth I/O groups IOG₀₀ to IOG₃₁ may have a spiral routing stack or a spiral routing structure, as shown in FIG. 3.

The first memory chip 171 may be divided into first to fourth regions R1, R2, R3, and R4. For example, the first to fourth regions R1, R2, R3, and R4 may respectively correspond to first, second, third, and fourth MATs. However, the disclosure is not limited thereto. The first, second, third, and fourth regions R1, R2, R3, and R4 may correspond to one of the first, second, third, and fourth MATs. For example, the TSV zones 171a, 171b, 171c, and 171d may be respectively arranged at the boundaries among the first, second, third, and fourth regions R1, R2, R3, and R4. For example, the TSV zone 171a may be arranged at the boundary between the first and second regions R1 and R2, the TSV zone 171b may be arranged at the boundary between the second and third regions R2 and R3, the TSV zone 171c may be arranged at the boundary between the third and fourth regions R3 and R4, and the TSV zone 171d may be arranged at the boundary between the first and fourth regions R1 and R4.

Devices connected to the first I/O groups IOG₀₀ and IOG₀₁ through the first redistribution patterns and devices connected to the fourth I/O groups IOG₃₀ and IOG₃₁ through the second redistribution patterns may be arranged in the first region R1. Devices connected to the first I/O groups IOG₀₀ and IOG₀₁ through the first redistribution patterns and devices connected to the second I/O groups IOG₁₀ and IOG₁₁ through the second redistribution patterns may be arranged in the second region R2. Devices connected to the third I/O groups IOG₂₀ and IOG₂₁ through the first redistribution patterns and devices connected to the second I/O groups IOG₁₀ and IOG₁₁ through the second redistribution patterns may be arranged in the third region R3. Devices connected to the third I/O groups IOG₂₀ and IOG₂₁ through the first redistribution patterns and devices connected to the fourth I/O groups IOG₃₀ and IOG₃₁ through the second redistribution patterns may be arranged in the fourth region R4. As described above, according to the present embodiment, the first memory chip 171 may include the devices connected to the first, second, third, and fourth I/O groups IOG₀₀, IOG₀₁, IOG₁₀, IOG₁₁, IOG₂₀, IOG₂₁, IOG₃₀ and IOG₃₁ arranged in the TSV zones 171a, 171b, 171c, and 171d. The above descriptions of the first memory chip 171 may also be applied to the second, third, and fourth memory chips 172 174.

The second memory chip 172 may include TSV zones 172a, 172b, 172c, and 172d. The first I/O groups IOG₀₀ and IOG₀₁ may be arranged in the TSV zone 172a and may be connected to the first redistribution patterns extending in the second direction HD2. The second I/O groups IOG₁₀ and IOG₁₁ may be arranged in the TSV zone 172b and may be connected to the second redistribution patterns extending in the first direction HD1. The third I/O groups IOG₂₀ and IOG₂₁ may be arranged in the TSV zone 172c and may be connected to the first redistribution patterns extending in the second direction HD2. The fourth I/O groups IOG₃₀ and IOG₃₁ may be arranged in the TSV zone 172d and may be connected to the second redistribution patterns extending in the first direction HD1.

The third memory chip 173 may include TSV zones 173a, 173b, 173c, and 173d. The third I/O groups IOG₂₀ and IOG₂₁ may be arranged in the TSV zone 173a and may be connected to the first redistribution patterns extending in the second direction HD2. The fourth I/O groups IOG₃₀ and IOG₃₁ may be arranged in the TSV zone 172b and may be connected to the second redistribution patterns extending in the first direction HD1. The first I/O groups IOG₀₀ and IOG₀₁ may be arranged in the TSV zone 173c and may be connected to the first redistribution patterns extending in the second direction HD2. The second I/O groups IOG₁₀ and IOG₁₁ may be arranged in the TSV zone 173d and may be connected to the second redistribution patterns extending in the first direction HD1.

The fourth memory chip 174 may include TSV zones 174a, 174b, 174c, and 174d. The third I/O groups IOG₂₀ and IOG₂₁ may be arranged in the TSV zone 174a and may be connected to the first redistribution patterns extending in the second direction HD2. The fourth I/O groups IOG₃₀ and IOG₃₁ may be arranged in the TSV zone 174b and may be connected to the second redistribution patterns extending in the first direction HD1. The first I/O groups IOG₀₀ and IOG₀₁ may be arranged in the TSV zone 174c and may be connected to the first redistribution patterns extending in the second direction HD2. The second I/O groups IOG₁₀ and IOG₁₁ may be arranged in the TSV zone 174d and may be connected to the second redistribution patterns extending in the first direction HD1.

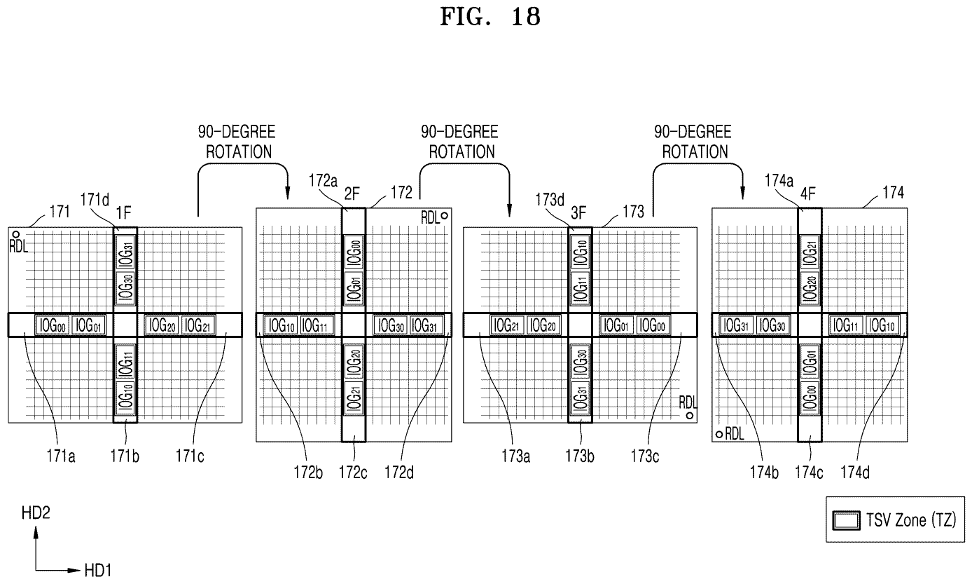

FIG. 18 illustrates an example of an arrangement of the first, second, third, and fourth memory chips 171, 172, 173, and 174, according to an embodiment.

Referring to FIG. 18, the example arrangement of the present embodiment may correspond to an example modification of the example arrangement of FIG. 17, and the descriptions given above with reference to FIG. 17 may also be applied to the present embodiment. The second memory chip 172 may be arranged with a 90-degree rotation relative to the first memory chip 171, the third memory chip 173 may be arranged with a 90-degree rotation relative to the second memory chip 172, and the fourth memory chip 174 may be arranged with a 90-degree rotation relative to the third memory chip 173 such that the first, second, third, and fourth memory chips 171, 172, 173, and 174 may support a 1-channel 4-way structure.

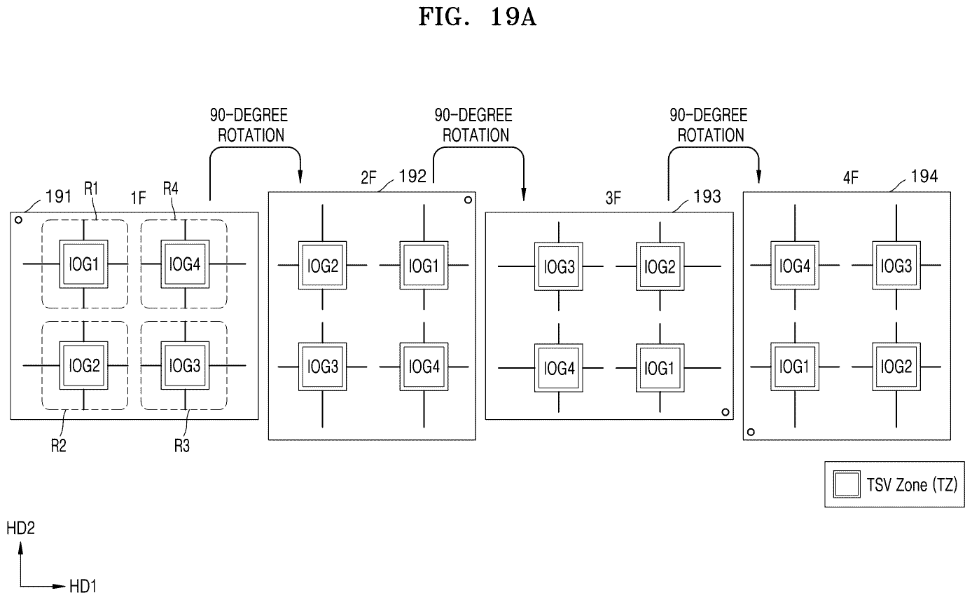

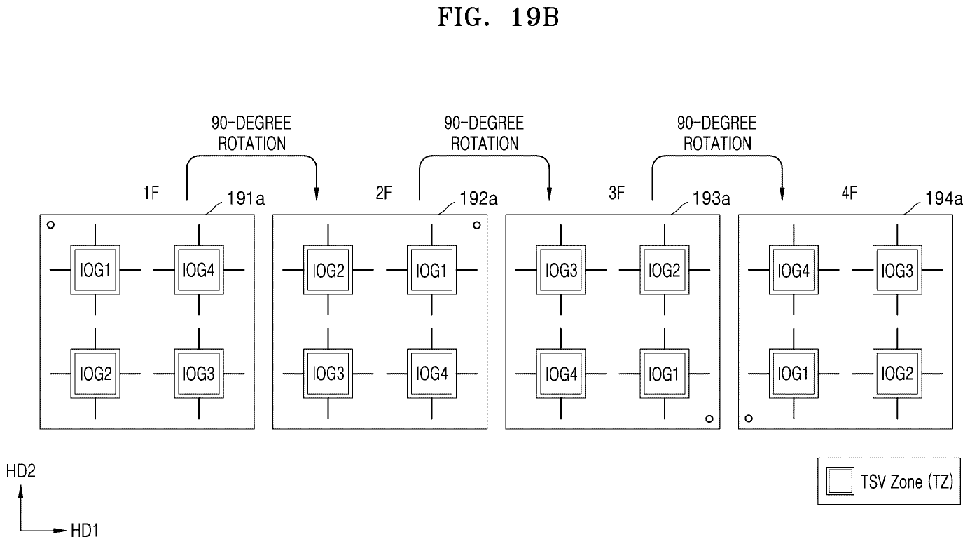

FIG. 19A illustrates an example of an arrangement of first, second, third, and fourth memory chips 191, 192, 193, and 194, according to an embodiment.

Referring to FIG. 19A, the first memory chip 191 may be arranged in the first floor 1F, the second memory chip 192 may be arranged in the second floor 2F, the third memory chip 193 may be arranged in the third floor 3F, and the fourth memory chip 194 may be arranged in the fourth floor 4F. The second memory chip 192 may be arranged with a 90-degree rotation relative to the first memory chip 191, the third memory chip 193 may be arranged with a 90-degree rotation relative to the second memory chip 192, and the fourth memory chip 194 may be arranged with a 90-degree rotation relative to the third memory chip 193 such that the first, second, third, and fourth memory chips 191, 192, 193, and 194 may support a 1-channel 4-way structure.

Each of the first, second, third, and fourth memory chips 191, 192, 193, and 194 may have the TSV zones TZ in which TSVs are arranged. For example, each of the first, second, third, and fourth memory chips 191192, 193, and 194 may be implemented in a rectangular shape. Each of the first, second, third, and fourth memory chips 191, 192, 193, and 194 may include the first, second, third, and fourth I/O groups IOG1, IOG2, IOG3, and IOG4 that are spaced apart from one another. Each of the first, second, third, and fourth I/O groups IOG1, IOG2, IOG3, and IOG4 may be connected to the first redistribution pattern extending in the second direction HD2 and the second redistribution pattern extending in the first direction HD1.

The first memory chip 191 may be divided into the first, second, third, and fourth regions R1, R2, R3, and R4. For example, the first, second, third, and fourth regions R1, R2, R3, and R4 may respectively correspond to the first, second, third, and fourth MATs. For example, the first, second, third, and fourth regions R1, R2, R3, and R4 may correspond to one of the first, second, third, and fourth MATs. For example, the TSV zones TZ may be respectively at the centers of the first, second, third, and fourth regions R1, R2, R3, and R4. For example, the first I/O group IOG1 in a TSV zone TZ may be arranged at the center of the first region R1, the second I/O group IOG2 in another TSV zone TZ may be arranged at the center of the second region R2, the third I/O group IOG3 in another TSV zone TZ may be arranged at the center of the third region R3, and the fourth I/O group IOG4 in another TSV zone TZ may be arranged at the center of the fourth region R4.

FIG. 19B illustrates an example of an arrangement of first, second, third, and fourth memory chips 191a, 192a, 193a, and 194a, according to an embodiment. Referring to FIG. 19B, the first, second, third, and fourth memory chips 191a, 192a, 193a, and 194a may correspond to an example modification of the first, second, third, and fourth memory chips 191, 192, 193, and 194 in FIG. 19A, and the descriptions given with reference to FIG. 19A may also be applied to the present embodiment. For example, each of the first, second, third, and fourth memory chips 191a, 192a, 193a, and 194a may be implemented in a square shape.

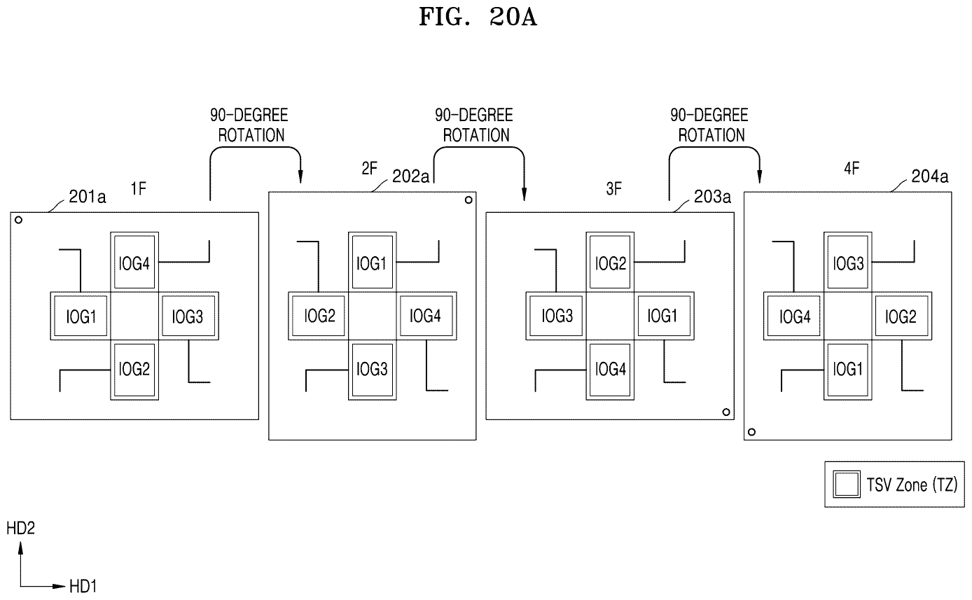

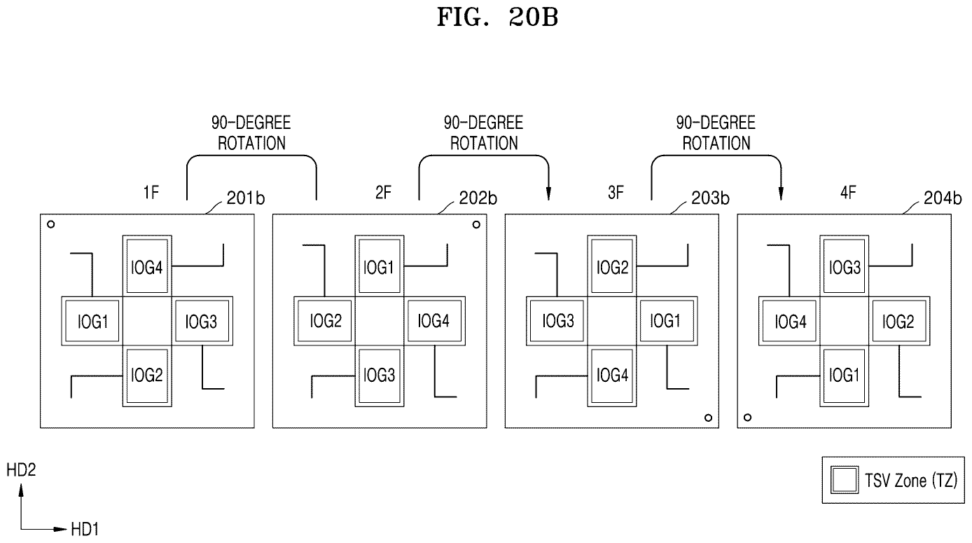

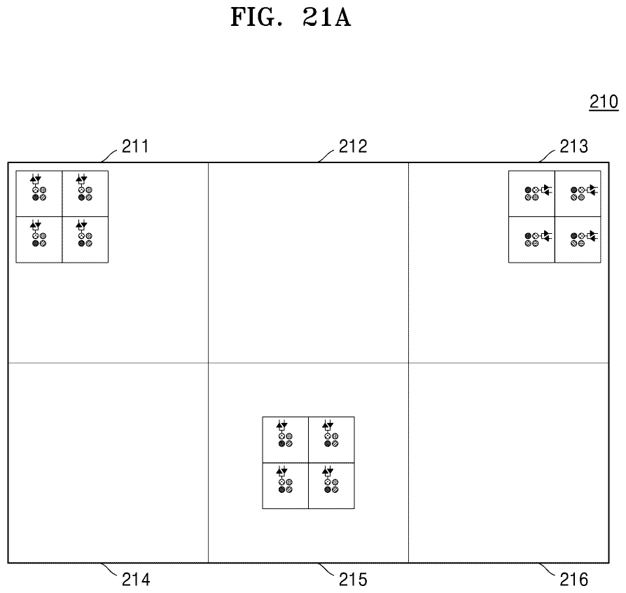

FIG. 20A illustrates an example of an arrangement of first, second, third, and fourth memory chips 201a, 202a, 203a, and 204a, according to an embodiment.

Referring to FIG. 20A, the first, second, third, and fourth memory chips 201a, 202a, 203a, and 204a may be respectively arranged in the first, second, third, and fourth floors 1F, 2F, 3F, and 4F. The second memory chip 202a may be arranged with a 90-degree rotation relative to the first memory chip 201a, the third memory chip 203a may be arranged with a 90-degree rotation relative to the second memory chip 202a, and the fourth memory chip 204a may be arranged with a 90-degree rotation relative to the third memory chip 203a such that the first to fourth memory chips 201a to 204a may support a 1-channel 4-way structure.

Each of the first, second, third, and fourth memory chips 201a, 202a, 203a, and 204a may have the TSV zones TZ in which TSVs are arranged. For example, each of the first, second, third, and fourth memory chips 201a, 202a, 203a, and 204a may be implemented in a rectangular shape. Each of the first, second, third, and fourth memory chips 201a, 202a, 203a, and 204a may include the first, second, third, and fourth I/O groups IOG1, IOG2, IOG3, and IOG4 that are spaced apart from one another. Each of the first, second, third, and fourth I/O groups IOG1, IOG2, IOG3, and IOG4 may be connected to a redistribution pattern extending in the first direction HD1 and the second direction HD2.

FIG. 20B illustrates an example of an arrangement of first, second, third, and fourth memory chips 201b, 202b, 203b, and 204b, according to an embodiment. Referring to FIG. 20B, the first, second, third, and fourth memory chips 201b, 202b, 203b, and 204b may correspond to an example modification of the first, second, third, and fourth memory chips 201a, 202a, 203a, and 204a in FIG. 20A, and the descriptions given with reference to FIG. 20A may also be applied to the present embodiment. For example, each of the first to fourth memory chips 201b to 204b may be implemented in a square shape.

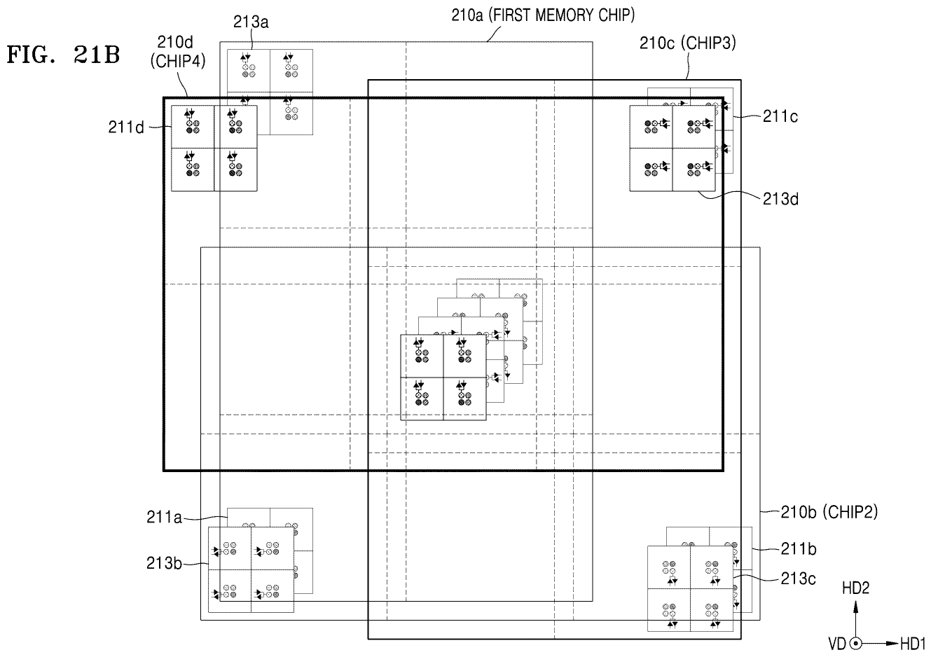

FIG. 21A illustrates a memory chip 210 according to an embodiment.

Referring to FIG. 21A, the memory chip 210 may include first, second, third, fourth, fifth, and sixth regions 211, 212, 213, 214, 215, and 216. For example, I/O units, which are independently connected to respective memory chips when the memory chips are stacked, may be arranged in the first and third regions 211 and 213. For example, the I/O units may be connected to the data signals DQ0, DQ1, DQ2, DQ3, DQ4, DQ5, DQ6,and DQ7. For example, I/O groups arranged in the third region 213 may have a 90-degree rotation relative to I/O groups arranged in the first region 211. For example, I/O units, which are connected in common to memory chips when the memory chips are stacked, may be arranged in the fifth region 215. For example, the I/O units may receive a command and/or an address. For example, the second, fourth, and sixth regions 212, 214, and 216 may correspond to logic regions, and a plurality of devices may be arranged in the second, fourth, and sixth regions 212, 214, and 216.

FIG. 21B illustrates an example of an arrangement of first, second, third, and fourth memory chips 210a, 210b, 210c, and 210d, according to an embodiment.

Referring to FIGS. 21A and 21B, the first, second, third, and fourth memory chips 210a, 210b, 210c, and 210d may be implemented by stacking memory chips 210 of FIG. 21A while sequentially rotating the memory chips 210 by 90 degrees. In this case, fifth regions 215 of the first to fourth memory chips 210a to 210d may overlap one another in the vertical direction VD such that I/O units arranged in the fifth region 215 may be connected in common to the first, second, third, and fourth memory chips 210a, 210b, 210c, and 210d. A first region 211a of the first memory chip 210a may overlap a third region 213b of the second memory chip 210b in the vertical direction VD, and a third region 213a of the first memory chip 210a may overlap a first region 211d of the fourth memory chip 210d in the vertical direction VD. A first region 211b of the second memory chip 210b may overlap a third region 213c of the third memory chip 210c in the vertical direction VD, and a first region 211c of the third memory chip 210c may overlap a third region 213d of the fourth memory chip 210d in the vertical direction VD.

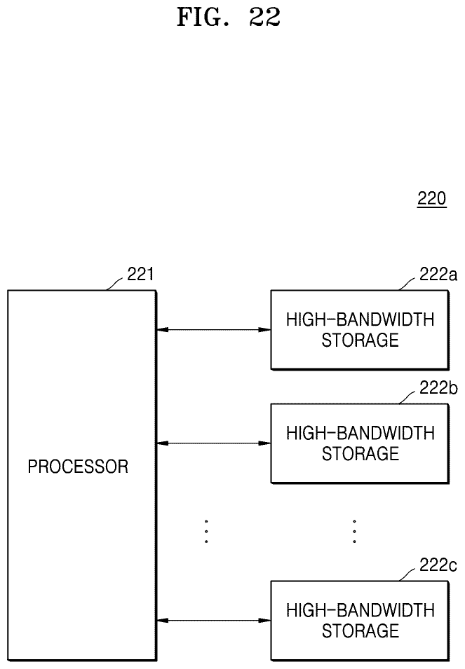

FIG. 22 is a block diagram of a system 220 according to an embodiment.

Referring to FIG. 22, the system 220 may include a processor 221 and high-bandwidth storages 222a, 222b, and 222c. In some embodiments, the system 220 may correspond to a single package, and the processor 221 and the high-bandwidth storages 222a, 222b, and 222c may be mounted on an interposer in the package. In some embodiments, the system 220 may correspond to a single module, and packages respectively including the processor 221 and the high-bandwidth storages 222a, 222b, and 222c may be mounted on a board.

The processor 221 may include a component that processes data. For example, the processor 221 may execute software code or may include fixed intellectual property (IP), such as a hardware accelerator, or a reconfigurable component, such as a field programmable gate array (FPGA). Alternatively, the processor 221 may include a component, such as a graphics processing unit (GPU) or a neural processing unit (NPU), which is designed for parallel processing.

The processor 221 may access the high-bandwidth storages 222a, 222b, and 222c. The processor 221 may write data to the high-bandwidth storages 222a, 222b, and 222c or read data from the high-bandwidth storages 222a, 222b, and 222c. In some embodiments, each of the high-bandwidth storages 222a, 222b, and 222c may correspond to a storage device or a memory device by referring to FIGS. 1 to 21B. When each of the high-bandwidth storages 222a, 222b, and 222c includes flash memory, each of the high-bandwidth storages 222a, 222b, and 222c may be referred to as an HBF memory device. As described above with reference to the accompanying drawings, a memory device included in each of the high-bandwidth storages 222a, 222b, and 222c may have wide I/O and provide multiple channels. Moreover, the memory device may support various modes. Therefore, the high-bandwidth storages 222a, 222b, and 222c may provide a high bandwidth and flexibility for the processor 221, and accordingly, the performance of the system 220 may be enhanced.

While the disclosure has been particularly shown and described with reference to embodiments thereof, it will be understood that various changes in form and details may be made therein without departing from the spirit and scope of the following claims.

What is claimed is:

1. A non-volatile memory device comprising:
a plurality of memory chips configured to communicate with a controller through a plurality of channels including a first channel, the plurality of memory chips being connected to each other through a spiral routing structure and stacked in a vertical direction,
wherein the plurality of memory chips include:
a first memory chip including a first input/output circuit and a first pin in a first region, the first input/output circuit and the first pin being connected to the first channel; and
a second memory chip including a second input/output circuit and a second pin in a second region, the second input/output circuit and the second pin being connected to the first channel, the second memory chip being stacked on the first memory chip with a first angle rotation in a horizontal direction, relative to the first memory chip, and
the second region has the first angle rotation in the horizontal direction, relative to the first region.

2. The non-volatile memory device of claim 1, wherein:
the first pin includes a first through silicon via (TSV) extending in the vertical direction, and
the second pin includes a second TSV extending in the vertical direction.

3. The non-volatile memory device of claim 1, wherein:
the first memory chip further includes:
a plurality of first through silicon vias (TSVs) respectively corresponding to the plurality of channels and extending in the vertical direction; and
a plurality of first redistribution layers implementing a first spiral routing stack by being connected to the plurality of first TSVs,
the second memory chip further includes:
a plurality of second TSVs respectively corresponding to the plurality of channels and extending in the vertical direction; and
a plurality of second redistribution layers implementing a second spiral routing stack by being connected to the plurality of second TSVs, and
the first spiral routing stack is connected to the second spiral routing stack through the plurality of second TSVs.

4. The non-volatile memory device of claim 1, wherein the plurality of memory chips further include:
a third memory chip including a third input/output circuit and a third pin in a third region, the third input/output circuit and the third pin being connected to the first channel, the third memory chip being stacked on the second memory chip with the first angle rotation in the horizontal direction, relative to the second memory chip; and
a fourth memory chip including a fourth input/output circuit and a fourth pin in a fourth region, the fourth input/output circuit and the fourth pin being connected to the first channel, the fourth memory chip being stacked on the third memory chip with the first angle rotation in the horizontal direction, relative to the third memory chip,
the third region has the first angle rotation in the horizontal direction, relative to the second region, and the fourth region has the first angle rotation in the horizontal direction, relative to the third region.

5. The non-volatile memory device of claim 4, wherein the first to fourth memory chips are configured to communicate with the controller in a 1-channel 4-way structure.

6. The non-volatile memory device of claim 1, wherein the first angle rotation is by 90 degrees.

7. The non-volatile memory device of claim 1, wherein:
each of the plurality of memory chips includes a plurality of input/output groups,
each of the plurality of input/output groups includes a plurality of input/output units, and
each of the plurality of input/output units includes a plurality of pins respectively corresponding to the plurality of channels.

8. A non-volatile memory device comprising:
a plurality of memory chips configured to communicate with a controller through a plurality of channels including a first channel and a second channel, the plurality of memory chips being connected to each other through a spiral routing structure and stacked in a vertical direction,
wherein the plurality of memory chips include:
a first memory chip including a first input/output circuit and a first pin in a first region, the first input/output circuit and the first pin being connected to the first channel;
a second memory chip including a second input/output circuit and a second pin in a second region, the second input/output circuit and the second pin being connected to the second channel, the second memory chip being stacked on the first memory chip; and
a third memory chip including a third input/output circuit and a third pin in a third region, the third input/output circuit and the third pin being connected to the first channel, the third memory chip being stacked on the second memory chip with a first angle rotation in a horizontal direction, relative to the second memory chip,
the first region and the second region overlap each other in the vertical direction, and
the third region has the first angle rotation in the horizontal direction, relative to the second region.

9. The non-volatile memory device of claim 8, wherein:
the first pin includes a first through silicon via (TSV) extending in the vertical direction,
the second pin includes a second TSV extending in the vertical direction, and
the third pin includes a third TSV extending in the vertical direction.

10. The non-volatile memory device of claim 8, wherein:
the first memory chip further includes:
a plurality of first through silicon vias (TSVs) respectively corresponding to the plurality of channels and extending in the vertical direction; and
a plurality of first redistribution layers implementing a first spiral routing stack by being connected to the plurality of first TSVs,
the second memory chip further includes:
a plurality of second TSVs respectively corresponding to the plurality of channels and extending in the vertical direction; and
a plurality of second redistribution layers implementing a second spiral routing stack by being connected to the plurality of second TSVs, and
the first spiral routing stack are connected to the second spiral routing stack through the plurality of second TSVs.

11. The non-volatile memory device of claim 8, wherein the plurality of memory chips further include:
a fourth memory chip including a fourth input/output circuit and a fourth pin in a fourth region, the fourth input/output circuit and the fourth pin being connected to the second channel, the fourth memory chip being stacked on the third memory chip, and
the third region and the fourth region overlap each other in the vertical direction.

12. The non-volatile memory device of claim 11, wherein the first to fourth memory chips are configured to communicate with the controller in a 2-channel 2-way structure.

13. The non-volatile memory device of claim 8, wherein the first angle rotation is by 180 degrees.

14. The non-volatile memory device of claim 8, wherein:
each of the plurality of memory chips includes a plurality of input/output groups,
each of the plurality of input/output groups includes a plurality of input/output units, and
each of the plurality of input/output units includes a plurality of pins respectively corresponding to the plurality of channels.

15. A non-volatile memory device comprising:
a plurality of memory chips configured to communicate with a controller through a plurality of channels, the plurality of memory chips being connected to each other through a spiral routing structure and stacked in a vertical direction,
wherein each of the plurality of memory chips includes:
at least one first input/output group in a first through silicon via (TSV) zone;
at least one second input/output group in a second TSV zone spaced apart from the first TSV zone;
first devices connected to the at least one first input/output group through a first redistribution pattern; and
second devices connected to the at least one second input/output group through a second redistribution pattern, and
at least one of the plurality of memory chips is stacked with a first angle rotation.

16. The non-volatile memory device of claim 15, wherein:
the plurality of memory chips include:
a first memory chip including a plurality of first TSVs and a plurality of first redistribution layers, the plurality of first TSVs respectively corresponding to the plurality of channels and extending in the vertical direction, and the plurality of first redistribution layers implementing a first spiral routing stack by being connected to the plurality of first TSVs; and
a second memory chip including a plurality of second TSVs and a plurality of second redistribution layers, the plurality of second TSVs respectively corresponding to the plurality of channels and extending in the vertical direction, and the plurality of second redistribution layers implementing a second spiral routing stack by being connected to the plurality of second TSVs, and
the first spiral routing stack are connected to the second spiral routing stack through the plurality of second TSVs.

17. The non-volatile memory device of claim 15, wherein each of the plurality of memory chips further includes:
at least one third input/output group in a third TSV zone;
at least one fourth input/output group in a fourth TSV zone spaced apart from the third TSV zone;
third devices connected to the at least one third input/output group; and
fourth devices connected to the at least one fourth input/output group.

18. The non-volatile memory device of claim 17, wherein:
the first and second TSV zones extend in a first direction,
the third and fourth TSV zones extend in a second direction that intersects with the first direction,
each of the plurality of memory chips is divided into first to fourth regions, and
the first to fourth TSV zones respectively correspond to boundaries among the first to fourth regions.

19. The non-volatile memory device of claim 17, wherein:
each of the plurality of memory chips is divided into first to fourth regions, and
the first to fourth TSV zones respectively correspond to centers of the first to fourth regions.

20. The non-volatile memory device of claim 15, wherein the first angle rotation is by 90 degrees or 180 degrees.
